(19) United States
(12) Patent Application Publication
(10) Pub. No.: US 2011/0275197 A1
(43) Pub. Date: Nov. 10, 2011

(54) SEMICONDUCTOR MEMORY DEVICE, METHOD OF FORMING THE SAME, AND MEMORY SYSTEM

(76) Inventors: Hong-bum PARK, Seongnam-si (KR); Dae-Han Yoo, Seoul (KR); Eun-Young Lee, Hwaseong-si (KR); Yongwoo Hyung, Yongin-si (KR); Youngsub You, Suwon-si (KR); Jinkwon Bok, Suwon (KR)

(21) Appl. No.: 13/100,680

(22) Filed: May 4, 2011

(30) Foreign Application Priority Data
May 4, 2010 (KR) 10-2010-0042081

(51) Int. Cl. H01L 21/20

(52) U.S. Cl. 438/478; 257/E21.09

(57) ABSTRACT

A method of forming a semiconductor memory device, a semiconductor memory device, and a memory system, the method including forming a thin film structure on a semiconductor substrate such that the thin film structure includes a plurality of thin films; patterning the thin film structure to form a through region in the thin film structure; forming a first silicon film using a first precursor such that the first silicon film covers the through region; and forming a second silicon film on the first silicon film using a second precursor, wherein the first precursor is different from the second precursor.

### CROSS REFERENCE TO RELATED APPLICATION

Korean Patent Application No. 10-2010-0042081, filed on May 4, 2010, in the Korean Intellectual Property Office, and entitled: “Semiconductor Memory Devices and Methods of Forming the Same,” is incorporated by reference herein in its entirety.

### BACKGROUND

1. Field

Embodiments relates to a semiconductor device, a method of forming the semiconductor device, and a memory system.

2. Description of the Related Art

To achieve high performance and low costs desired by consumers, integration of semiconductor devices should be improved. The integration of semiconductor memory devices may be a significant factor in determining the cost of a product. Thus, it may be desirable for semiconductor memory devices to have a high degree of integration. The integration degree of a two-dimensional or plane-type memory device may be determined by an area a unit memory cell. Thus, the integration degree may depend on a level of a pattern miniaturization technology. However, the integration degree of a two-dimension semiconductor memory device may be limited.

Thus, three-dimension memory devices including three-dimensionally arrayed memory cells have been suggested.

### SUMMARY

Embodiments are directed to a semiconductor device, a method of forming the semiconductor device, and a memory system.

The embodiments may be realized by providing a method of forming a semiconductor memory device, the method including forming a thin film structure on a semiconductor substrate such that the thin film structure includes a plurality of thin films; patterning the thin film structure to form a through region in the thin film structure; forming a first silicon film using a first precursor such that the first silicon film covers the through region; and forming a second silicon film on the first silicon film using a second precursor, wherein the first precursor is different from the second precursor.

A grain size of the first silicon film may be greater than a grain size of the second silicon film.

The first precursor may be a disilane first precursor, and the second precursor may be a silane second precursor.

Forming the first silicon film may include forming a first preliminary silicon film using the disilane first precursor; and performing a heat treatment process on the first preliminary silicon film to re-crystallize the first preliminary silicon film.

The heat treatment process may be performed after the second silicon film is formed.

The method may further include forming a third silicon film on the second silicon film, wherein the third silicon film is formed using a disilane precursor and a silane precursor.

The first precursor may be a trisilane first precursor, and the second precursor may be a silane second precursor.

The method may further include forming a third silicon film on the second silicon film, wherein the third silicon film is formed using a trisilane precursor and a silane precursor.

The method may further include forming a third silicon film covering the through region prior to forming of the first silicon film, wherein the third silicon film is formed using a trisilane precursor, the first precursor is a disilane first precursor, and the second precursor is a silane second precursor.

The thin film structure may include first insulation films and second insulation films, and the first insulation films and second insulation films may be alternately stacked.

The method may further include forming a dividing region extending through the first insulation film and the second insulation film; selectively removing portions of the second insulation film exposed through the dividing region to form an undercut region such that the undercut region exposes portions of the first silicon film between the first insulation films; and forming a gate pattern such that the gate pattern fills the undercut region.

The method may further include forming an information storage film between the gate pattern and the first silicon film.

Forming the information storage film may include forming a charge trap layer having a charge trap site.

Forming the thin film structure may include forming insulation films and conductive films such that the insulation films and the conductive films are alternately stacked.

Patterning the thin film structure may include patterning the conductive film to form conductive patterns, and a semiconductor film including the first silicon film and the second silicon film may be a channel region of three-dimensionally arrayed transistors.

The method may further include forming an information storage film between the conductive patterns and the semiconductor film.

Forming the information storage film may include forming a charge trap layer having a charge trap site.

The embodiments may also be realized by providing a semiconductor memory device including gate patterns and insulation patterns alternately stacked on a semiconductor substrate; semiconductor patterns passing through the gate patterns and the insulation patterns and extending upwardly from the semiconductor substrate; and an information storage film between the semiconductor patterns and the gate patterns, wherein the semiconductor patterns include a first silicon film adjacent to the information storage film and a second silicon film on the first silicon film, and the first silicon film has a grain size greater than a grain size of the second silicon film.

The semiconductor memory device may further include a third silicon film on the second silicon film, wherein the grain size of the second silicon film is greater than a grain size of the third silicon film.

The embodiments may also be realized by providing a memory system including a controller; an input/output device; a memory, the memory including a semiconductor memory device of an embodiment; an interface; and a bus, wherein the memory is in communication with the input/output device through the bus, the memory stores commands executed by the controller, and the interface is in communication with the controller, the memory, and the input/output device through the bus and with an external communication network.

### BRIEF DESCRIPTION OF THE DRAWINGS

The embodiments will become more apparent to those of ordinary skill in the art by describing in detail exemplary embodiments with reference to the attached drawings, in which:

FIG. 1 illustrates a circuit diagram of a semiconductor memory device according to an embodiment;

FIG. 2 illustrates a flowchart describing a method of forming a semiconductor memory device according to an embodiment;

FIGS. 3 through 5 and FIGS. 7 through 13 illustrate perspective views of stages in a method of forming a semiconductor memory device according to an embodiment;

FIGS. 6A and 6B illustrate images showing grain sizes of a silicon film according to an embodiment;

FIG. 14 illustrates an enlarged view of a portion A of FIG. 13;

FIGS. 15 through 24 illustrate perspective views of stages in a method of forming a semiconductor memory device according to a another embodiment;

FIGS. 25 through 33 illustrate perspective views of stages in a method of forming a semiconductor memory device according to yet another embodiment;

FIGS. 34 through 42 illustrate perspective views of stages in a method of forming a semiconductor memory device according to still another embodiment;

FIG. 43 illustrates a flowchart describing a method of forming a semiconductor memory device according to another embodiment;

FIG. 44 illustrates a perspective view of a modification of the method described with reference to FIG. 5;

FIG. 45 illustrates a flowchart describing a method of forming a semiconductor memory device according to yet another embodiment;

FIG. 46 illustrates a graph showing channel current characteristics of semiconductor memory devices according to an embodiment;

FIGS. 47A through 47D illustrate graphs showing standard deviations of channel currents with respect to gate lines according to an embodiment;

FIGS. 48 through 50 illustrate schematic sectional views of stages in a method of forming a semiconductor memory device according to an embodiment;

FIG. 51 illustrates a block diagram of a memory system including a semiconductor memory device formed according to an embodiment;

FIG. 52 illustrates a block diagram of a memory card including a semiconductor memory device formed according to an embodiment; and

FIG. 53 illustrates a block diagram of an information processing system provided with a semiconductor memory device formed according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

The embodiment in the detailed description will be described with cross-sectional views and/or plan views as ideal exemplary views of the inventive concept. In the figures, the dimensions of layers and regions are exaggerated for clarity of illustration. Accordingly, shapes of the exemplary views may be modified according to manufacturing techniques and/or tolerances. Therefore, the embodiments of the inventive concept are not limited to the specific shape illustrated in the exemplary views, but may include other shapes that may be created according to manufacturing processes. For example, an etched region illustrated as a rectangle may have rounded or curved features. Areas exemplified in the drawings have general properties, and are used to illustrate a specific shape of a device region. Thus, this should not be construed as limited to the scope of the present invention. Also, though terms like a first, a second, and a third are used to describe various components in various embodiments of the inventive concept, the components are not limited to these terms. These terms are only used to distinguish one component from another component. Embodiments described and exemplified herein include complementary embodiments thereof.

In the following description, the technical terms are used only for explaining a specific exemplary embodiment while not limiting the inventive concept. The terms of a singular form may include plural forms unless referred to the contrary. The meaning of ‘comprises’ and/or ‘comprising’ does not exclude other components besides a mentioned component.

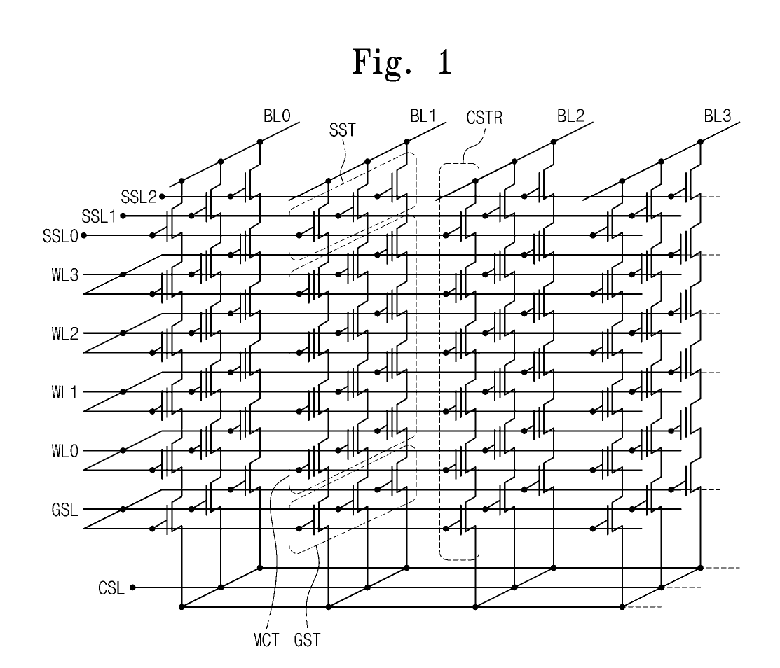

FIG. 1 illustrates a circuit diagram of a semiconductor memory device according to an embodiment.

Referring to FIG. 1, the semiconductor memory device according to an embodiment may include a common source line CSL; a plurality of bit lines BL0, BL1, BL2, and BL3; and a plurality of cell strings CSTR between the common source line CSL and the bit lines BL0, BL1, BL2, and BL3.

The common source line CSL may be a conductive thin film on a semiconductor substrate or an impurity region formed within the substrate. The bit lines BL0, BL1, BL2, and BL3 may be conductive patterns (e.g., metal lines) spaced apart from the semiconductor substrate and at an upper side thereof. The bit lines BL0 BL1, BL2, and BL3 may be two-dimensionally arrayed, each being connected with the cell strings CSTR that are arrayed in parallel. Accordingly, the cell strings CSTR may be two-dimensionally arrayed on the common source line CSL or the substrate.

Each of the cell strings CSTR may include a ground selection transistor GST (connected to the common source line CSL); a string selection transistor SST (connected to the bit line BL0, BL1, BL2, or BL3); and a plurality of memory cell transistors MCT between the ground selection transistor GST and the string selection transistor SST. The ground selection transistor GST, the string selection transistor SST, and the memory cell transistors MCT may be connected in series to one another. A ground selection line GSL, a plurality of word lines WL0 to WL3, and a plurality of string selection lines SSL0 to SSL2 (between the common source line CSL and the bit lines BL0, BL1, BL2, and BL3), may be used as gate electrodes of the ground selection transistors GST, the memory cell transistors MCT, and the string selection transistors SST, respectively.

The ground selection transistors GST may each be spaced substantially the same distance from the substrate. The gate electrodes of the ground selection transistors GST may be connected in common to the ground selection line GSL, and thus, may be in an equipotential state. Accordingly, the ground selection line GSL may be a plate-shaped or comb-shaped conductive pattern between the common source line CSL and a memory cell transistor MCT closest to the common source line CSL. In a similar manner, the gate electrodes of the memory cell transistors MCT (spaced substantially the same distance from the common source line CSL), may also be connected in common to one of the word lines WL0 to WL3 and thus may be in an equipotential state. Accordingly, each of the word lines WL0 to WL3 may be a plate-shaped or comb-shaped conductive pattern parallel to the upper surface of the substrate. The single cell string CSTR may be constituted by the memory cell transistors MCT having different distances from the common source line CSL. Thus, the word lines WL0 to WL3 may be arrayed in a multi layer between the common source line CSL and the bit lines BL0 to BL3.

Each of the cell strings CSTR may include a semiconductor pillar that extends vertically from the common source line CSL and connects to the bit line BL0, BL1, BL2, or BL3. The semiconductor pillars may pass through the ground selection line GSL and the word lines WL0 to WL3. The semiconductor pillar may include impurity regions on a body thereof and one end or both ends of the body. For example, a drain region may be formed at an upper end of the semiconductor pillar.

An information storage film may be between the word lines WL0 to WL3 and the semiconductor pillar. According to an embodiment, the information storage film may be an electric charge storage film. For example, the information storage film may include one of a trap insulation film and an insulation film including a floating gate electrode or conductive nano dots.

A dielectric film (which may be used as a gate insulation film of the ground selection transistor GST or the string selection transistor SST) may be disposed between the ground selection line GSL and the semiconductor pillar or between the string selection lines SSL and the semiconductor pillar. The gate insulation film of at least one of the ground selection transistors GST and the string selection transistors SST may be formed of the same material as that of the information storage film of the memory cell transistor MCT, or may be a, e.g., silicon oxide film, gate insulation film for a metal-oxide-semiconductor field-effect transistor (MOSFET).

The ground selection transistors GST, the string selection transistors SST, and the memory cell transistors MCT may be a MOSFET that uses the semiconductor pillar as a channel region. In an implementation, the semiconductor pillar, the ground selection line GSL, the string selection lines SSL, and the word lines WL0 to WL3 may constitute an MOS capacitor. In this case, the ground selection transistor GST, the memory cell transistors MCT, and the string selection transistor SST may share an inversion field that is formed by a fringe field from the ground selection line GSL, the word lines WL0 to WL3, and the string selection lines SSL, and thus, may be electrically connected to one another.

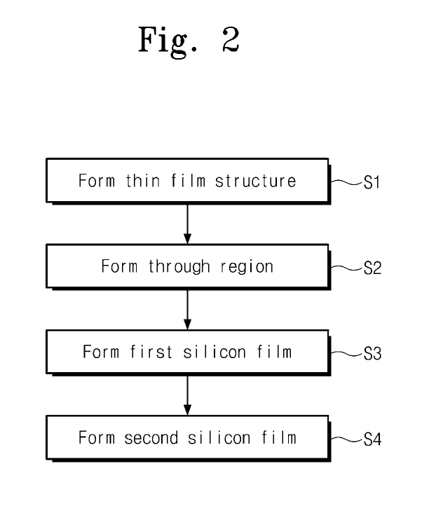

FIG. 2 illustrates a flowchart describing a method of forming a semiconductor memory device according to an embodiment.

Referring to FIG. 2, a thin film structure (including a plurality of thin films) may be formed on a semiconductor substrate in operation S1. The thin film structure may be patterned to form through regions in the thin film structure in operation S2. Then, a first silicon film covering the through regions may be formed in operation S3. A second silicon film may be formed on the first silicon film in operation S4. The first silicon film and the second silicon film may be formed using different precursors, e.g., a first precursor and a second precursor, respectively. A grain size of the first silicon film may be greater than a grain size of the second silicon film.

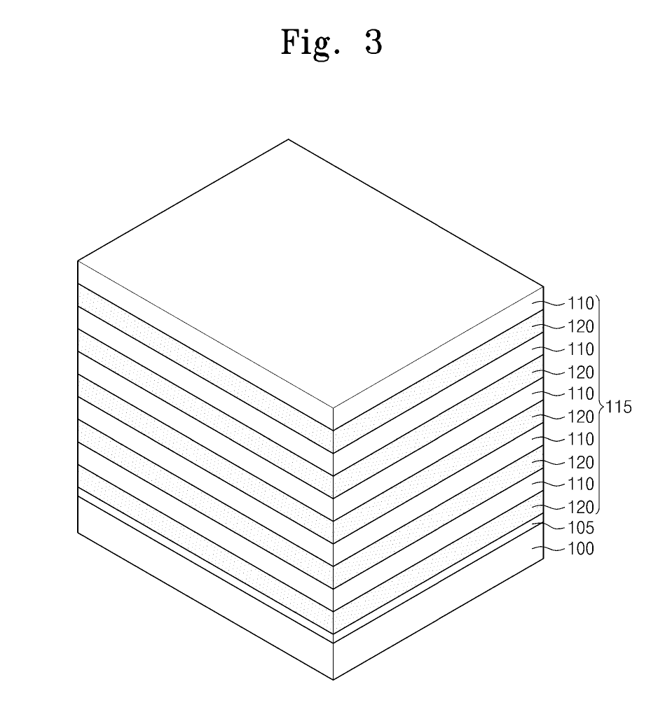

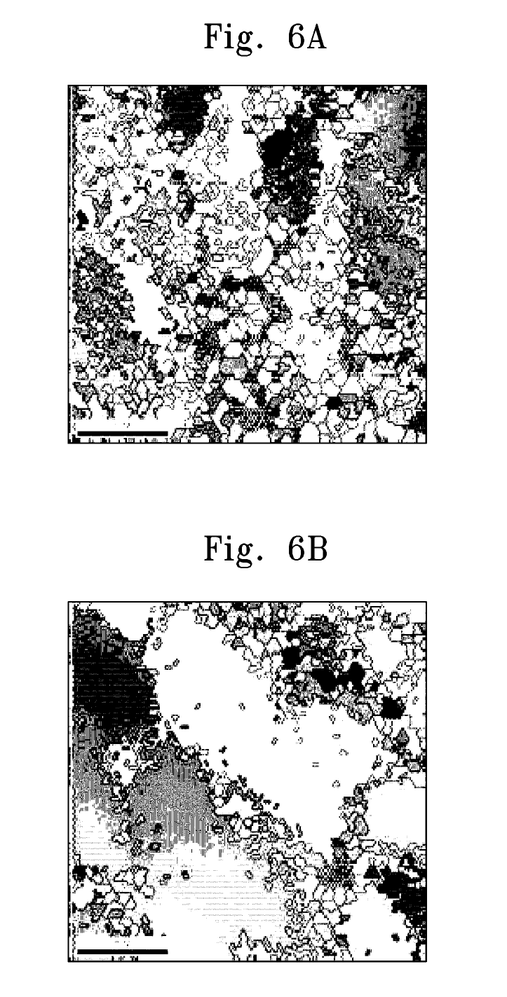

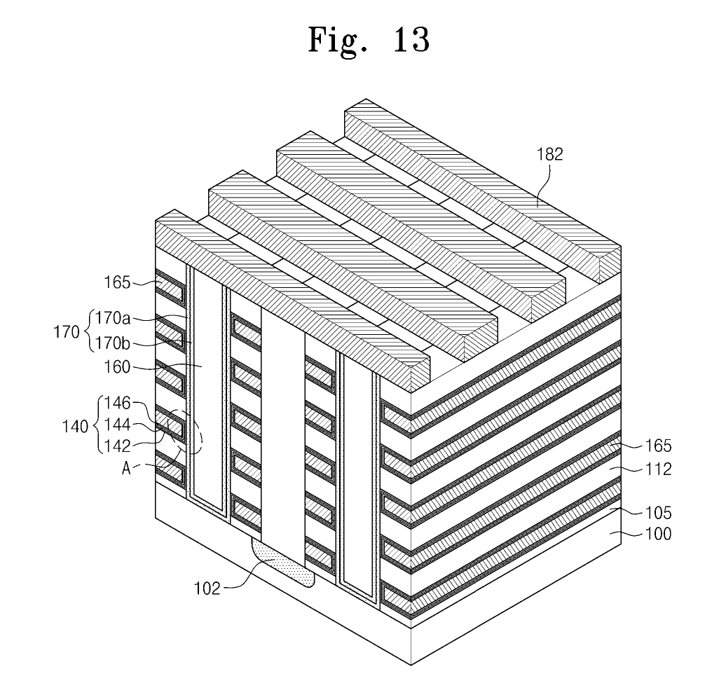

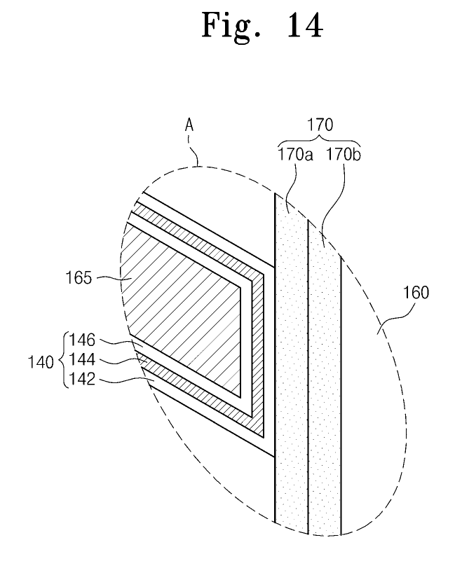

FIGS. 3 through 5 and FIGS. 7 through 13 illustrate perspective views of stages in a method of forming a semiconductor memory device according to an embodiment. FIGS. 6A and 6B illustrate images showing grain sizes of a silicon film according to an embodiment. FIG. 14 illustrates an enlarged view of a portion A of FIG. 13.

Referring to FIGS. 2 and 3, a thin film structure 115 including a plurality of thin films on a semiconductor substrate 100 may be formed in operation S1. The thin film structure 115 may include first insulation films 110 and second insulation films 120, which may be sequentially and repeatedly, e.g., alternately, stacked. For example, the thin film structure 115 may include the first insulation films 110 (that are sequentially stacked) and the second insulation films 120 between the first insulation films 110. The first insulation films 110 may have a different wet etch rate from that of the second insulation films 120. For example, the first insulation films 110 may be formed of a silicon oxide; and the second insulation films 120 may be formed of a silicon nitride. A buffer insulation film 105 may be between the thin film structure 115 and the semiconductor substrate 100. The buffer insulation film 105 may be formed of a silicon oxide.

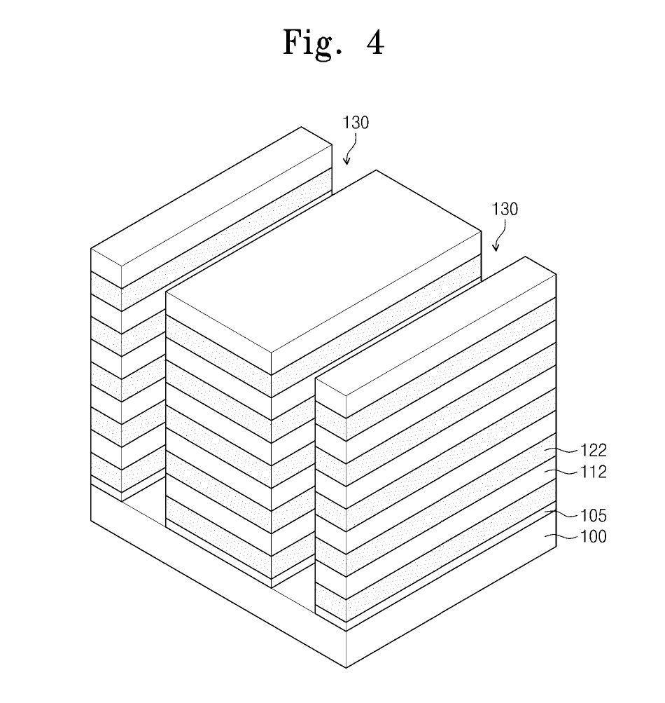

Referring to FIGS. 2 and 4, the thin film structure 115 may be patterned to form a plurality of through regions 130 exposing an upper surface of the semiconductor substrate 100 in operation S2. In patterning the thin film structure 115, the first insulation films 110 and the second insulation films 120 may be patterned to form first insulation patterns 112 and second insulation patterns 122, respectively. For example, during forming of the through regions 130, a mask pattern (not shown) defining two-dimensional positions of the through regions 130 may be formed on the thin film structure 115; and the thin film structure 115 may be anisotropically etched using the mask pattern as an etch mask. The through regions 130 may be formed two-dimensionally and regularly. In an implementation, the through regions 130 may be in the form of trenches exposing the upper surface of the semiconductor substrate 100 and having a rectangular bottom surface, as illustrated in FIG. 4.

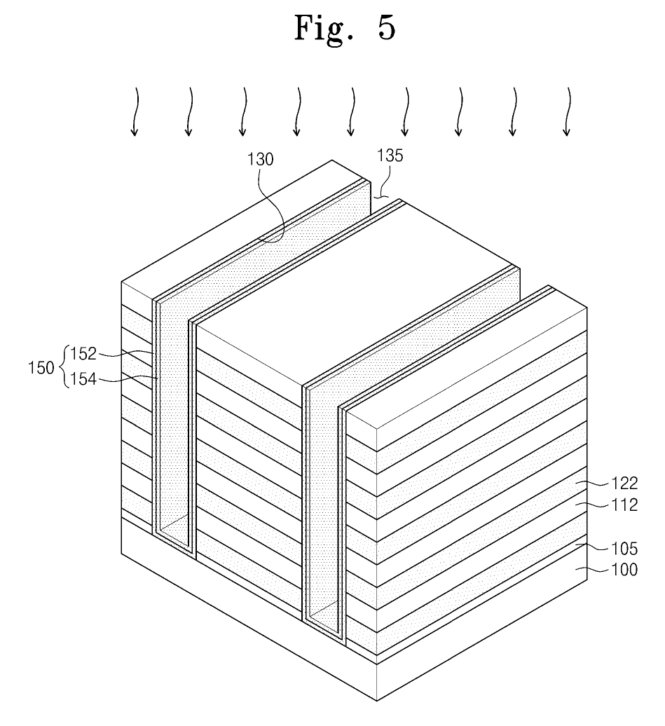

Referring to FIGS. 2 and 5, a first silicon film 152 (covering the through regions 130) may be formed in operation S3. A second silicon film 154 may be formed on the first silicon film 152 in operation S4. The first silicon film 152 and the second silicon film 154 may constitute a semiconductor film 150. The first silicon film 152 and the second silicon film 154 may define gap regions 135 within the through regions 130. The first silicon film 152 and the second silicon film 154 may be formed using different precursors, e.g., first and second precursors, respectively. A grain size of the first silicon film 152 may be greater than a grain size of the second silicon film 154.

The first silicon film 152 and the second silicon film 154 may be formed using, e.g., a chemical vapor deposition method. In an implementation, first silicon film 152 may be formed using a precursor of disilane (Si₂H₆), e.g., the first precursor; and the second silicon film 154 may be formed using a precursor of silane (SiH₄), e.g., the second precursor. The first silicon film 152 and the second silicon film 154 may be formed through a continuous in-situ process.

In forming the first silicon film 152, a first preliminary silicon film (not shown) may be formed using the disilane precursor; and a heat treatment process may be performed on the first preliminary silicon film to re-crystallize the first preliminary silicon film. Re-crystallizing the first preliminary silicon film may increase the grain size of the first silicon film 152. The heat treatment process may be performed by supplying nitrogen gas or water vapor, e.g., at an elevated temperature. The heat treatment process may be performed after the second silicon film 154 is formed. In an implementation, the heat treatment process may be performed as a wet oxidation process in which water vapor is supplied, e.g., at an elevated temperature.

As will be described in greater detail below, the first silicon film 152 and the second silicon film 154 may be channel regions of the semiconductor memory device. The first silicon film 152 formed using the precursor of disilane (Si₂H₆) may have a large grain size to ensure an excellent cell current characteristic. This may be due to the precursor of disilane (Si₂H₆) having two silicon atoms. Thus, nucleation and growth of an island seed may be facilitated. In an implementation, the first silicon film 152 may have a grain size of about 1 μm or greater.

Referring to FIGS. 6A and 6B, a silicon film formed using a silane precursor may have a mean grain size of about 0.379 μm; and a silicon film formed using a disilane precursor may have a mean grain size of about 1.417 μm. Accordingly, characteristics of a cell current may be determined according to a grain size. A grain boundary may degrade mobility of electric charges. Thus, as a grain size increases, a density of a grain boundary decreases, and a resistance value may decrease.

The second silicon film 154 formed using the precursor of silane (SiH₄) may have an excellent step coverage properties. Thus, even if the through regions 130 has a large aspect ratio (e.g., about 50 or greater), a uniform thin film may be formed. Excellent cell current ensured by the grain size of the first silicon film 152 may be complementary to excellent step coverage properties ensured by the second silicon film 154.

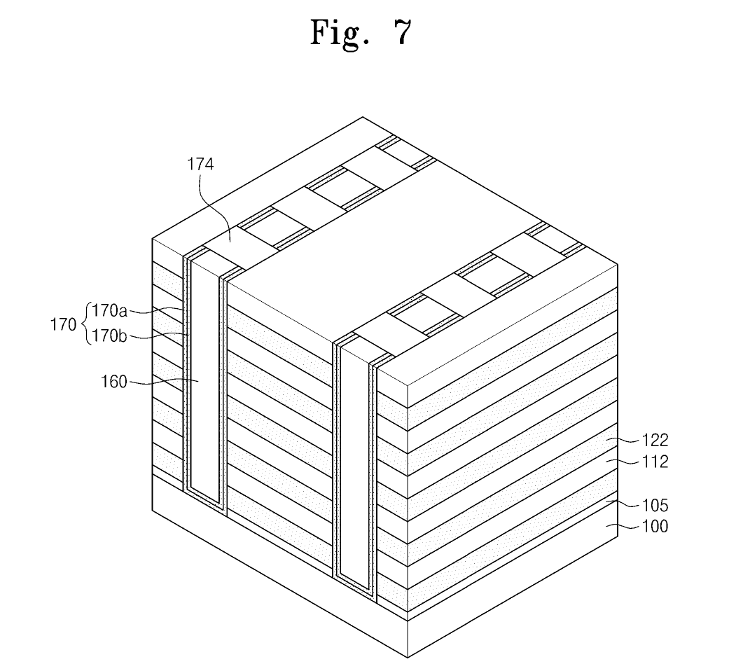

Referring to FIG. 7, a filling film 160 may be formed within the through regions 130. The filling film 160 may fill the gap regions 135. The filling film 160 may be formed by forming an insulation film (not illustrated) filling the gap regions 135 and then performing a planarization process on the insulation film. Alternatively, the first silicon film 152 and the second silicon film 154 completely fill the through regions 130. Thus, in an implementation, the filling film 160 may be unnecessary and may be omitted.

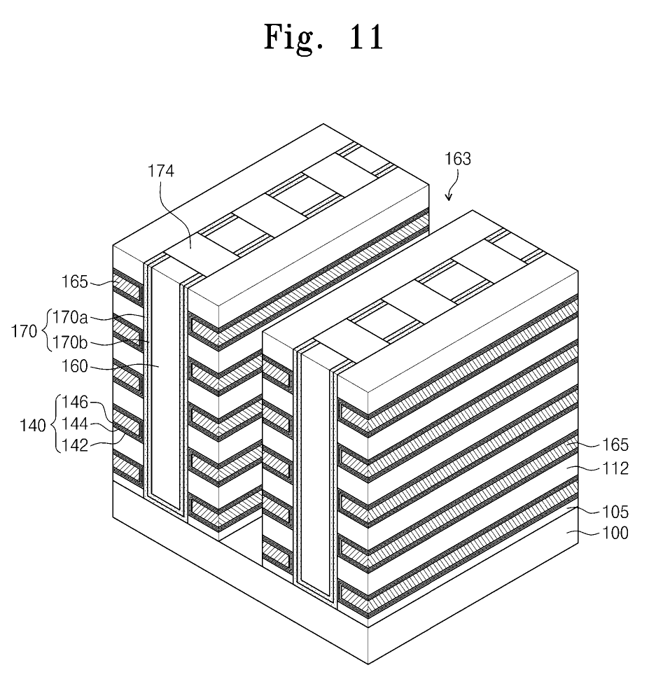

The first silicon film 152 and the second silicon film 154 may be patterned to form semiconductor patterns 170 extending upwardly from the semiconductor substrate 100 within the through regions 130. The semiconductor patterns 170 may extend to cross side walls of gate patterns 165 (see FIG. 11).

The semiconductor patterns 170 may include first silicon patterns 170a (formed by patterning the first silicon film 152) and second silicon patterns 170b (formed by patterning the second silicon film 154). The semiconductor patterns 170 and the gate patterns 165 may constitute transistors that are arrayed three-dimensionally. Forming the semiconductor patterns 170 may include forming division regions. The division regions may divide the first silicon film 152 and the second silicon film 154. A gap-fill insulation film 174 may be formed in the division regions. The gap-fill insulation film 174 may include, e.g., a silicon oxide film.

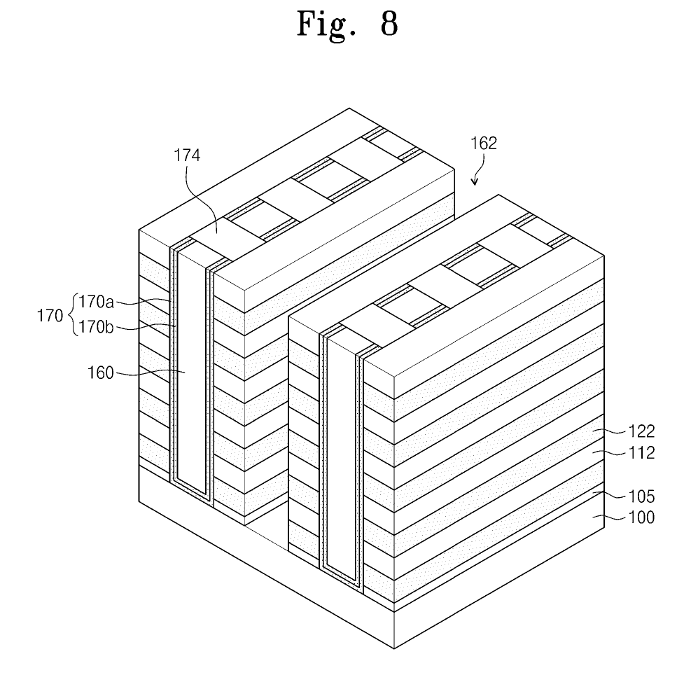

Referring to FIG. 8, a first dividing region 162 (which may divide the first insulation patterns 112 and the second insulation patterns 122 between parts of both the filling film 160 and the gap-fill insulation film 174 and may expose the semiconductor substrate 100) may be formed. The first dividing region 162 may be formed through an anisotropic etch process. The first dividing region 162 may be formed between the filling films 160.

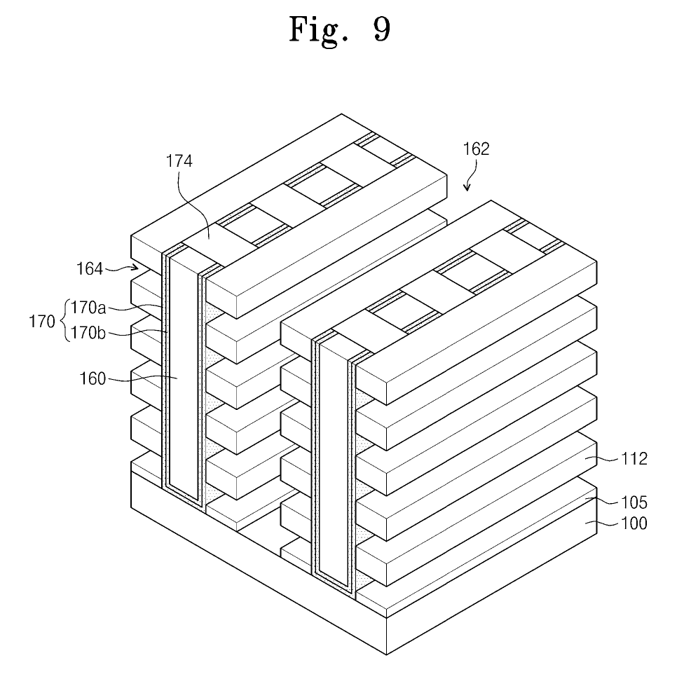

Referring to FIG. 9, the second insulation patterns 122 (exposed by the first dividing region 162) may be removed to form undercut regions 164. The second insulation patterns 122 may be removed to expose portions of the semiconductor patterns 170 between the first insulation patterns 112. The second insulation patterns 122 may be removed through a wet etch process. For example, the second insulation patterns 122 may have an etch selectivity with respect to the first insulation patterns 112.

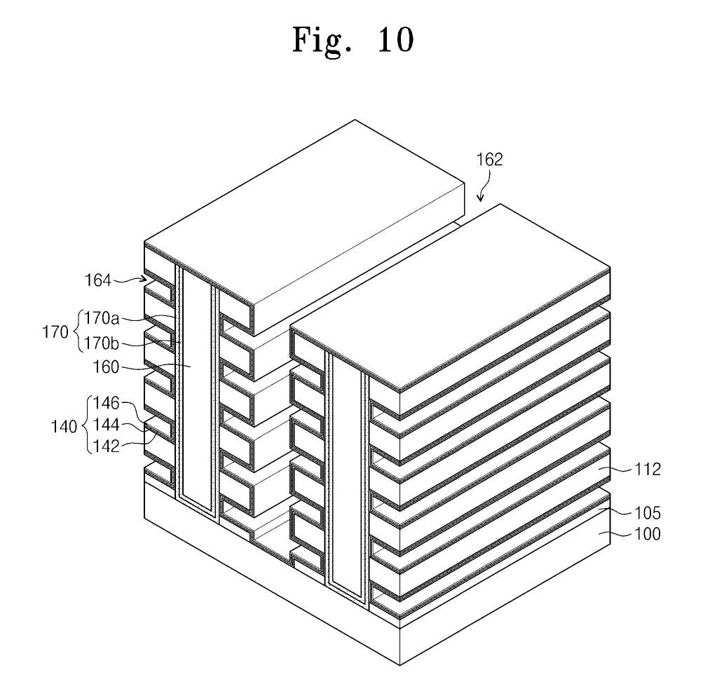

Referring to FIG. 10, an information storage film 140 (which may cover exposed portions of the first insulation patterns 112 and exposed portions of semiconductor patterns 170) may be formed. The information storage film 140 may include, e.g., a charge trap layer 144 having a charge trap site. For example, the information storage film 140 may include a tunnel insulation film 142 (contacting the semiconductor patterns 170), the charge trap layer 144 (on the tunnel insulation film 142), and a blocking insulation film 146 (on the charge trap layer 144). The charge trap layer 144 may include, e.g., a silicon nitride film, the tunnel insulation film 142 may include, e.g., a silicon oxide film or a multi-layered insulation film including a silicon oxide film, and the blocking insulation film 146 may be formed of a high dielectric material (e.g., aluminum oxide or hafnium oxide). In FIG. 10, the information storage film 140 is illustrated as three thin films, but the embodiments are not limited thereto, and the information storage film 140 may include three or more thin films provided that data may be stored.

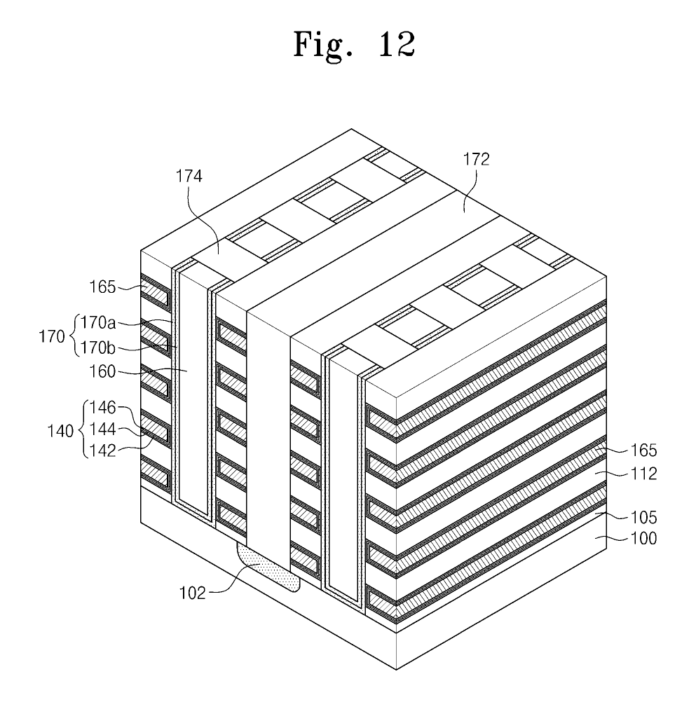

Referring to FIG. 11, the gate patterns 165 may be formed in the undercut regions 164 between the first insulation patterns 112. The gate patterns 165 may be formed of, e.g., polysilicon or metal. The gate patterns 165 may have a line shape extending in one direction. Forming the gate patterns 165 may include forming a gate conductive film (not illustrated) between the first insulation patterns 112 (having the information storage film 140 thereon), and forming a second dividing region 163 that divides the gate conductive film by patterning the gate conductive film. The second dividing region 163 and the first dividing region 162 may be formed at the same position and may expose side walls of the first insulation patterns 112. A common source region 102 (see FIG. 12) may be formed in portions of the semiconductor substrate 100 exposed by the second dividing region 163. The common source region 102 may be formed through an ion implantation process.

Referring to FIG. 12, a dividing insulation film 172 (filling the second dividing region 163) may be formed. The dividing insulation film 172 may be formed of, e.g., a silicon oxide. The dividing insulation film 172 may be formed by forming an insulation film filling the second dividing region 163 and then performing a planarization process on the insulation film.

Referring to FIG. 13, bit lines 182 (that are electrically connected to the semiconductor patterns 170) may be formed. An extension direction of the bit lines 182 may cross that of the gate patterns 165. In an implementation, contact plugs (not illustrated) may be formed between the bit lines 182 and the semiconductor patterns 170.

According to the present embodiment, the semiconductor patterns 170 may have excellent cell current characteristics and excellent step coverage properties, thereby improving uniformity of the semiconductor patterns 170.

FIG. 14 illustrates an enlarged view of the portion A of FIG. 13, which shows a transistor of the semiconductor memory device according to the present embodiment. As described above, the semiconductor patterns 170 may extend upwardly from the semiconductor substrate and may include the first silicon pattern 170a and the second silicon pattern 170b. An extension direction of the gate patterns 165 may cross that of the semiconductor patterns 170. The information storage film 140 may be between the gate pattern 165 and the semiconductor pattern 170. The information storage film 140 may include the tunnel insulation film 142 (adjacent to the semiconductor pattern 170), the charge trap layer 144 (on the tunnel insulation film 142), and the blocking insulation film 146 (on the charge trap layer 144). The first silicon patterns 170a may have a different grain size from that of the second silicon patterns 170b. In an implementation, the grain size of the first silicon patterns 170a may be greater than that of the second silicon patterns 170b.

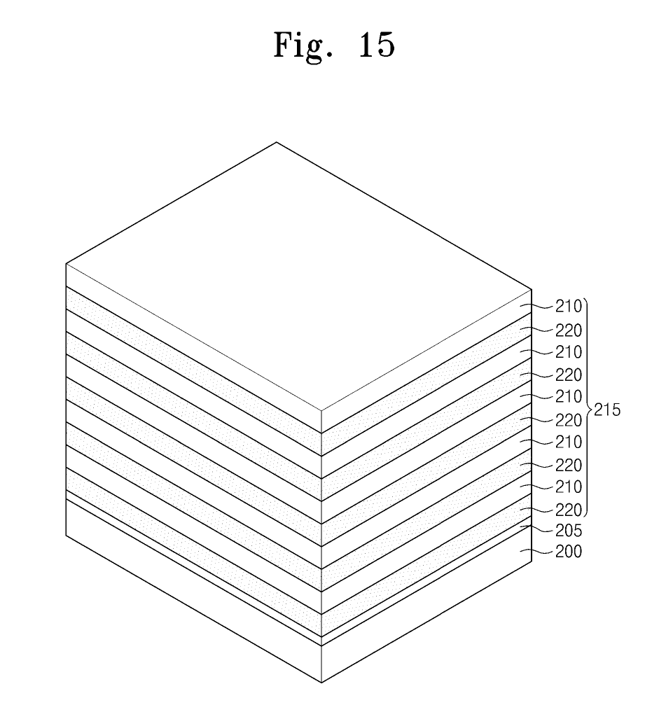

FIGS. 15 through 24 illustrate perspective views of stages in a method of forming a semiconductor memory device according to another embodiment. Here, a repeated description of the same elements and/or steps as that of the previous embodiment will be omitted.

Referring to FIGS. 2 and 15, a thin film structure 215 (including a plurality of thin films on a semiconductor substrate 200) may be formed in operation S1. The thin film structure 215 may include first insulation films 210 and second insulation films 220, which may be sequentially and repeatedly, e.g., alternately, stacked. For example, the thin film structure 215 may include the first insulation films 210 (that are sequentially stacked) and the second insulation films 220 between the first insulation films 210. The first insulation films 210 may have a different wet etch rate from that of the second insulation films 220. For example, the first insulation films 210 may be formed of a silicon oxide and the second insulation films 220 may be formed of a silicon nitride. A buffer insulation film 205 may be between the thin film structure 215 and the semiconductor substrate 200. The buffer insulation film 205 may be formed of, e.g., a silicon oxide.

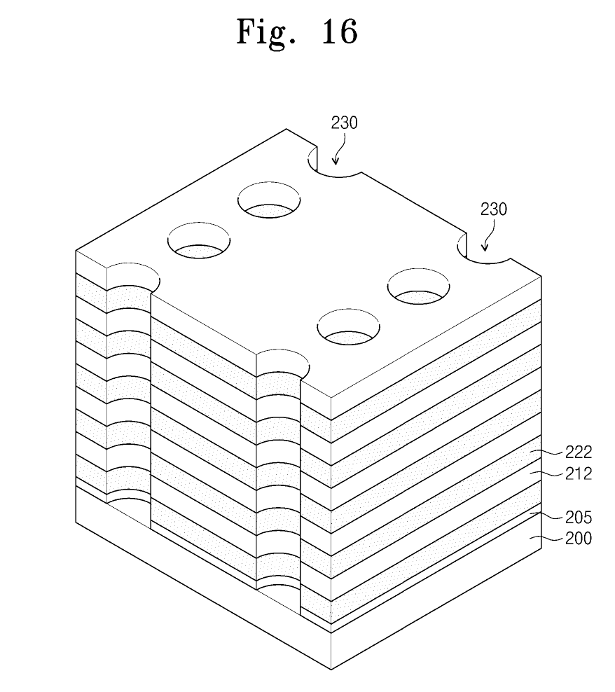

Referring to FIGS. 2 and 16, a plurality of through regions 230 (exposing an upper surface of the semiconductor substrate 200) may be formed by patterning the thin film structure 215 in operation S2. Forming the through regions 230 may include forming first insulation patterns 212 and second insulation patterns 222 by patterning the first insulation films 210 and the second insulation films 220, respectively. For example, the through regions 230 may be formed by forming a mask pattern (not shown) defining two-dimensional positions of the through regions 230 on the thin film structure 215 and anisotropically etching the thin film structure 215 using the mask pattern as an etch mask. The through regions 230 may be formed two-dimensionally and regularly. In an implementation, the through regions 230 may have hole shapes exposing the upper surface of the semiconductor substrate 200 and having a circular bottom surface, as illustrated in FIG. 16.

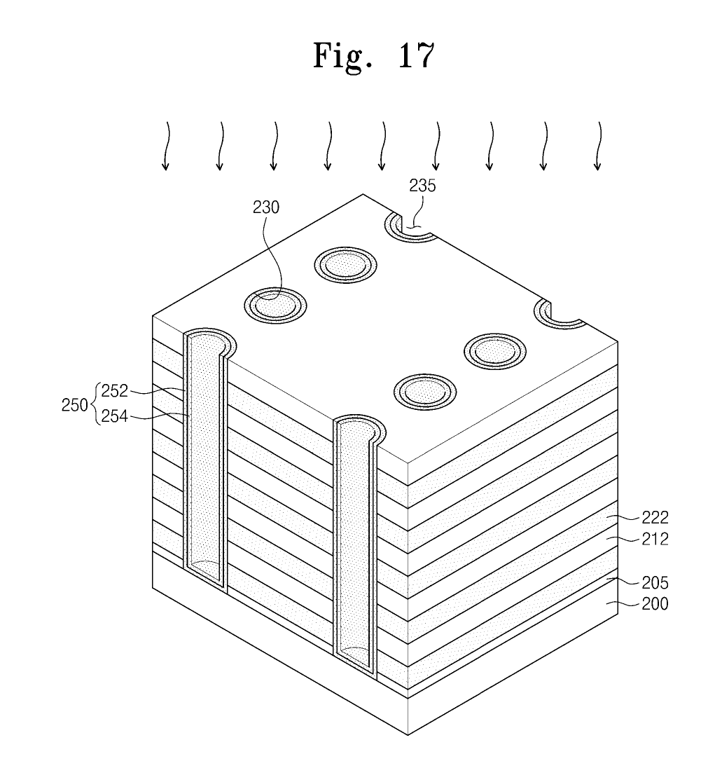

Referring to FIGS. 2 and 17, a first silicon film 252 covering the through regions 230 may be formed in operation S3. A second silicon film 254 may be formed on the first silicon film 252 in operation S4. The first silicon film 252 and the second silicon film 254 may constitute a semiconductor film 250. The first silicon film 252 and the second silicon film 254 may define gap regions 235 within the through regions 230. The first silicon film 252 and the second silicon film 254 may be formed using different precursors, e.g., first and second precursors, respectively. A grain size of the first silicon film 252 may be greater than a grain size of the second silicon film 254.

The first silicon film 252 and the second silicon film 254 may be formed using, e.g., a chemical vapor deposition method. The first silicon film 252 may be formed using a precursor of disilane (Si₂H₆), e.g., first precursor; and the second silicon film 254 may be formed using a precursor of silane (SiH₄), e.g., second precursor. The first silicon film 252 and the second silicon film 254 may be formed through a continuous in-situ process.

To form the first silicon film 252, a first preliminary silicon film (not shown) may be formed using the disilane precursor, and a heat treatment process may be performed on the first preliminary silicon film to re-crystallize the first preliminary silicon film. Re-crystallizing the first preliminary silicon film may increase the grain size of the first silicon film 252. The heat treatment process may be performed by supplying nitrogen gas or water vapor, e.g., at an elevated temperature. The heat treatment process may be performed after the second silicon film 254 is formed. The heat treatment process may be performed as a wet oxidation process in which water vapor is supplied, e.g., at an elevated temperature.

As will be described in greater detail below, the first silicon film 252 and the second silicon film 254 may be channel regions of the semiconductor memory device. The first silicon film 252 (formed using the precursor of disilane (Si₂H₆)) may have a large grain size to ensure an excellent cell current characteristic. This may be due to the precursor of disilane (Si₂H₆) having two silicon atoms. Thus, nucleation and growth of an island seed may be facilitated. In an implementation, the first silicon film 252 may have a grain size of about 1 μm or greater.

The second silicon film 254 (formed using the precursor of silane (SiH₄)) may have excellent step coverage properties. Even if the through regions 230 have a large aspect ratio (e.g., about 50 or greater), the second silicon film 254 may still exhibit excellent step coverage properties. Thus, a uniform thin film may be formed. Excellent cell current ensured by the grain size of the first silicon film 252 may be complementary to excellent step coverage properties ensured by the second silicon film 254.

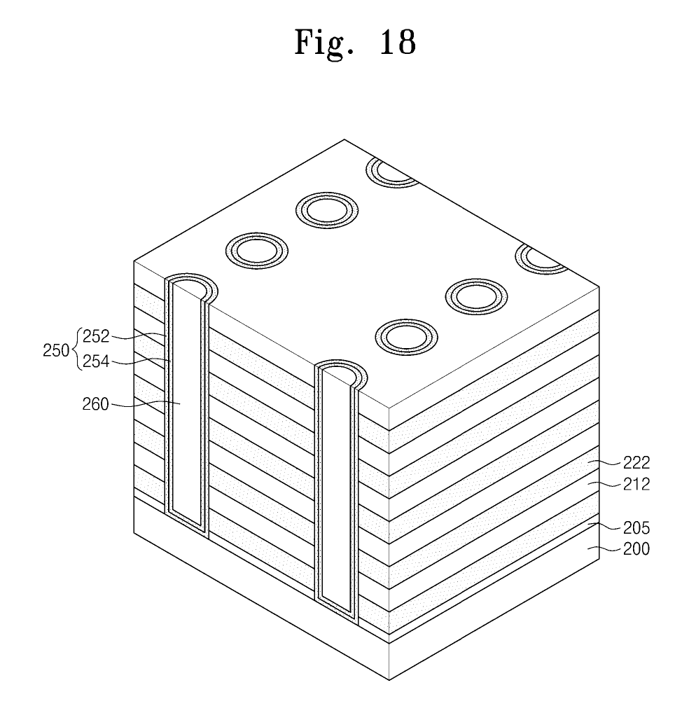

Referring to FIG. 18, a filling film 260 may be formed within the through regions 230. The filling film 260 may fill the gap regions 235. The filling film 260 may be formed by forming an insulation film (not illustrated) filling the gap regions 235 and then performing a planarization process on the insulation film. In an implementation, the first silicon film 252 and the second silicon film 254 may completely fill the through regions 230. Thus, in an implementation, the filling film 260 may be unnecessary and may be omitted.

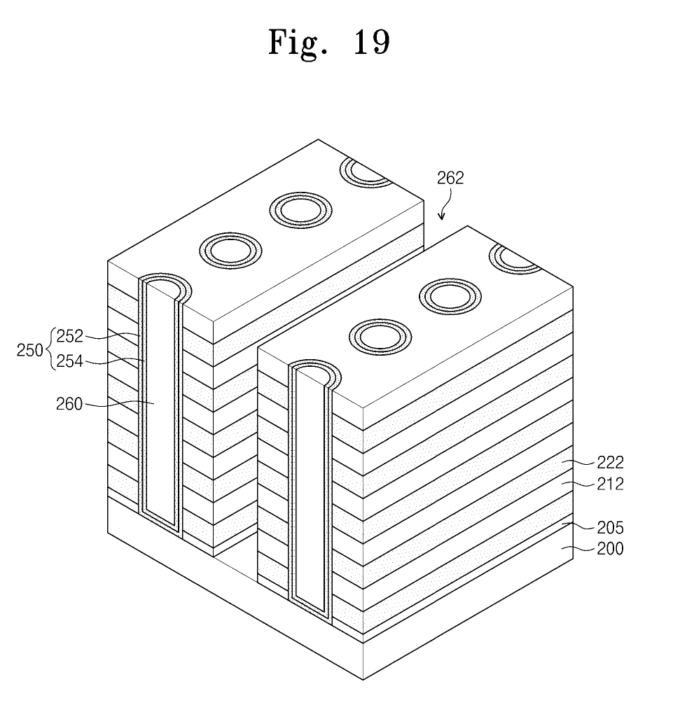

Referring to FIG. 19, a first dividing region 262 (that divides the first insulation patterns 212 and the second insulation patterns 122 between parts of the filling film 260 and exposes the semiconductor substrate 200) may be formed. The first dividing region 262 may be formed by, e.g., an anisotropic etch process. The first dividing region 262 may be formed between the parts of the filling film 260 and may be parallel to the filling film 260.

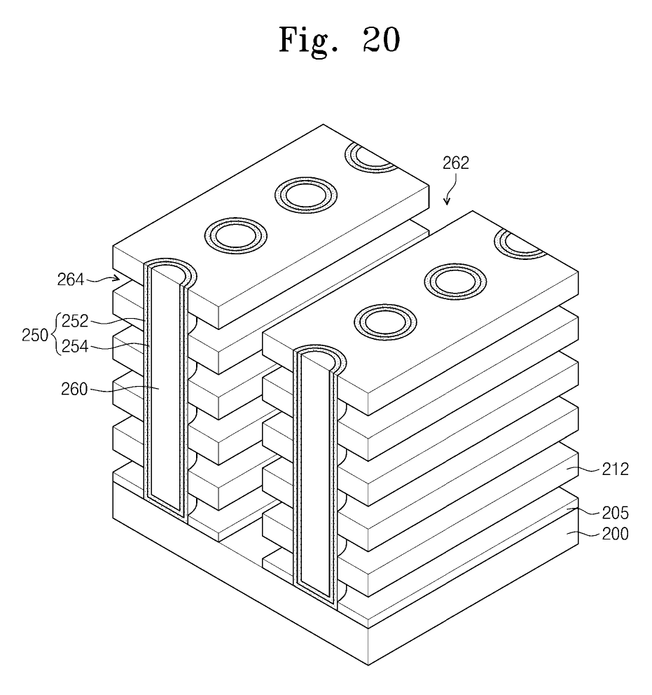

Referring to FIG. 20, portions of the second insulation patterns 222 exposed by the first dividing region 262 may be removed to form undercut regions 264. For example, the second insulation patterns 222 may be removed to expose potions of the semiconductor film 250 between the first insulation patterns 212. The second insulation patterns 222 may be removed through a wet etch process. For example, the second insulation patterns 222 may have an etch selectivity with respect to the first insulation patterns 212.

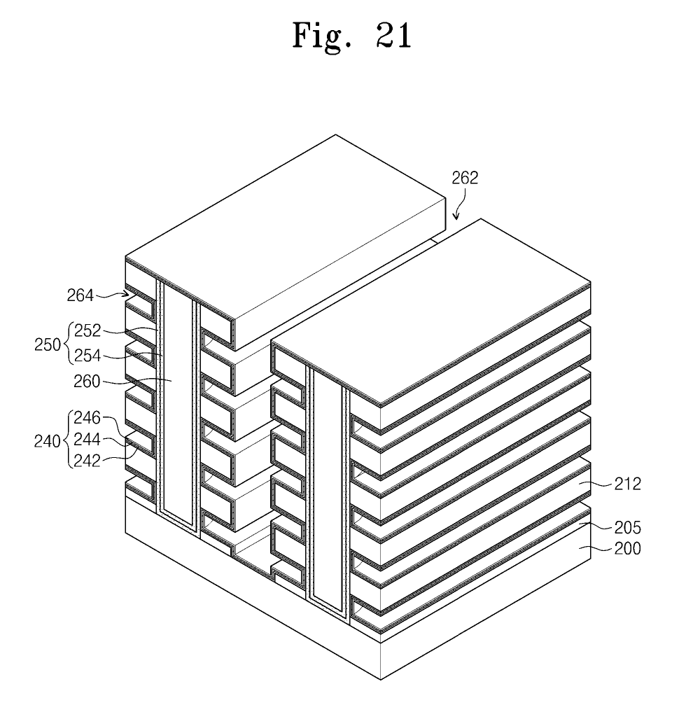

Referring to FIG. 21, an information storage film 240 (which may cover exposed portions of first insulation patterns 212 and exposed portions of semiconductor film 250) may be formed. The information storage film 240 may include a charge trap layer 244 having a charge trap site. For example, the information storage film 240 may include a tunnel insulation film 242 contacting the semiconductor film 250, the charge trap layer 244 on the tunnel insulation film 242, and a blocking insulation film 246 on the charge trap layer 244. The charge trap layer 244 may include, e.g., a silicon nitride film, the tunnel insulation film 242 may include, e.g., a silicon oxide film or a multi-layered insulation film including a silicon oxide film, and the blocking insulation film 246 may be formed of a high dielectric material (e.g., aluminum oxide or hafnium oxide). In FIG. 21, the information storage film 240 is illustrated as three thin films, but the embodiments are not limited thereto, and the information storage film 240 may include three or more thin films, provided that data can be stored.

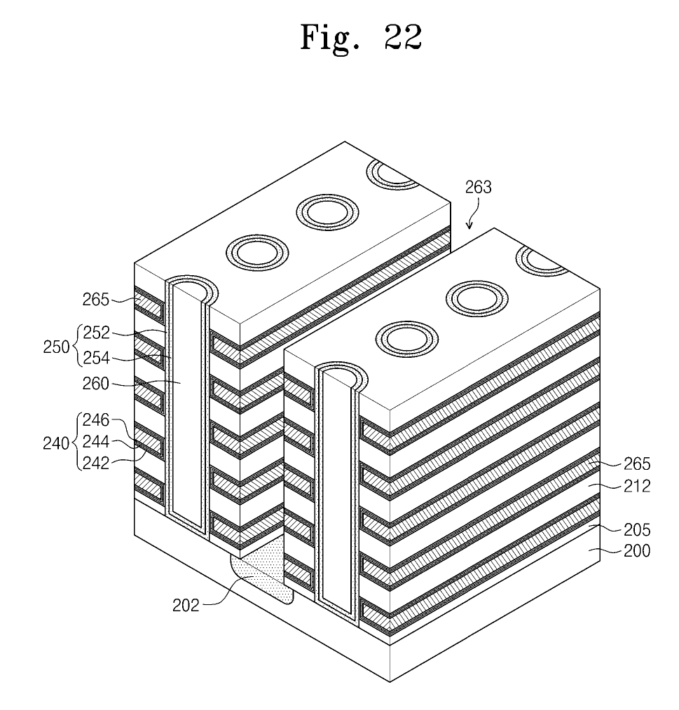

Referring to FIG. 22, gate patterns 265 may be formed in the undercut regions 264 between the first insulation patterns 212. The gate patterns 265 may be formed of, e.g., polysilicon or metal. The gate patterns 265 may have a line shape extending in one direction. In forming the gate patterns 265, a gate conductive film (not illustrated) may be formed between the first insulation patterns 212 (having the information storage film 240 thereon); and the gate conductive film may be patterned to form a second dividing region 263 that divides the gate conductive film. The second dividing region 263 and the first dividing region 262 may be formed at the same position and may expose side walls of the first insulation patterns 212. A common source region 202 may be formed in portions of the semiconductor substrate 200 exposed by the second dividing region 263. The common source region 202 may be formed through, e.g., an ion implantation process.

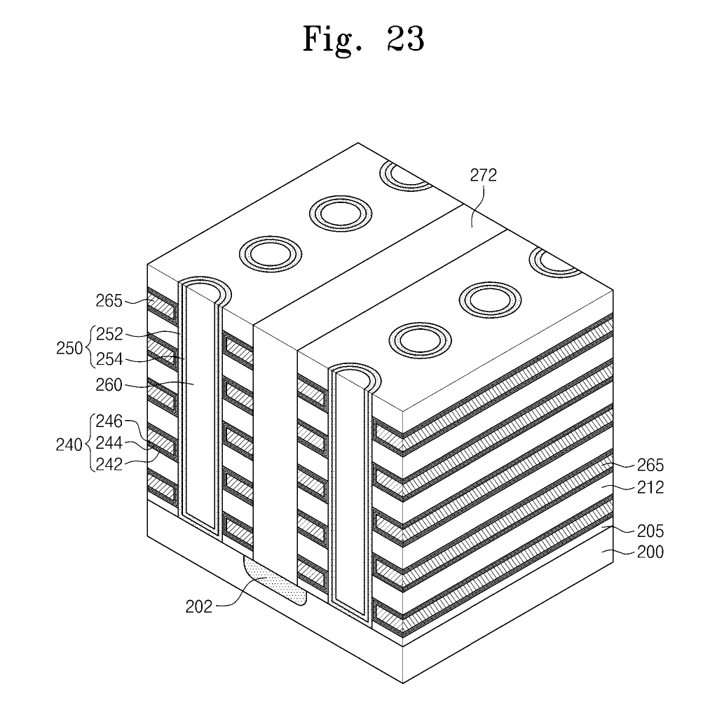

Referring to FIG. 23, a dividing insulation film 272 (filling the second dividing region 263) may be formed. The dividing insulation film 272 may be formed of, e.g., a silicon oxide. The semiconductor film 250 and the gate patterns 265 may constitute transistors that are arrayed three-dimensionally.

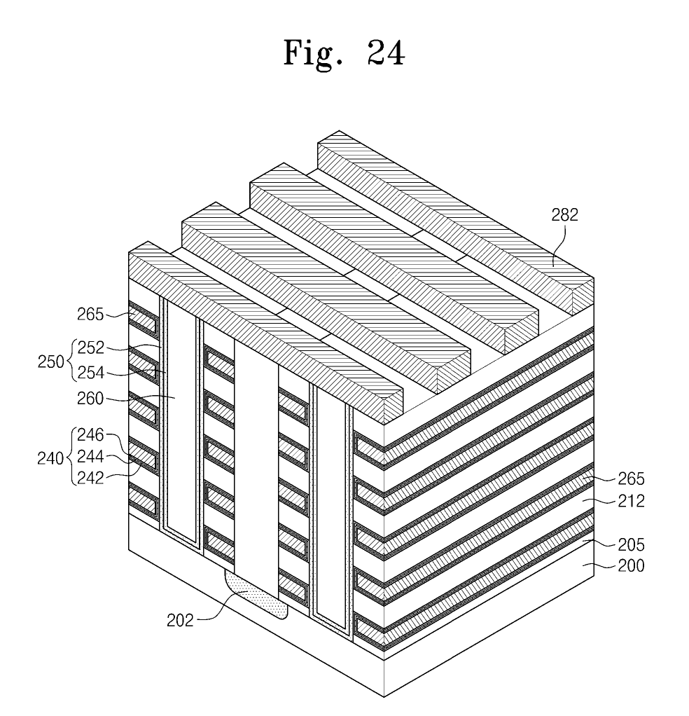

Referring to FIG. 24, bit lines 282 (that are electrically connected to the semiconductor film 250) may be formed. An extension direction of the bit lines 282 may cross that of the gate patterns 265. Alternatively, contact plugs (not illustrated) may be formed between the bit lines 282 and the semiconductor film 250.

According to the present embodiment, the semiconductor film 250 may have excellent cell current characteristics and excellent step coverage properties, thereby improving uniformity of the semiconductor film 250.

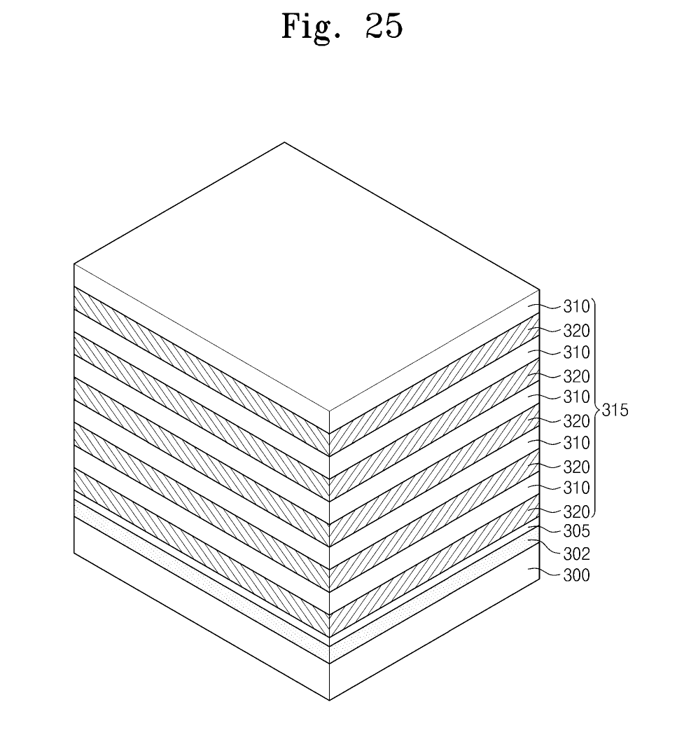

FIGS. 25 through 33 illustrate perspective views of stages in a method of forming a semiconductor memory device according to yet another embodiment. Here, a repeated description of the same parts and/or steps as that of the previous embodiment will be omitted.

Referring to FIGS. 2 and 25, a thin film structure 315 including a plurality of thin films on a semiconductor substrate 300 may be formed in operation S1. The semiconductor substrate 300 may be formed of single crystalline silicon. In another implementation, the semiconductor substrate 300 may be formed of a semiconductor material providing another semiconductor characteristic.

The thin film structure 315 may include insulation films 310 and conductive films 320, which may be sequentially and repeatedly, e.g., alternately, stacked. For example, the thin film structure 315 may include the insulation films 310 that are sequentially stacked and the conductive films 320 between the insulation films 310. The insulation films 310 may be formed of, e.g., a silicon oxide or a silicon nitride. The conductive films 320 may be formed of, e.g., a metal or a polycrystalline silicon doped with impurities. A buffer insulation film 305 may be disposed between the semiconductor substrate 300 and the thin film structure 315. The buffer insulation film 305 may be formed of, e.g., a silicon oxide.

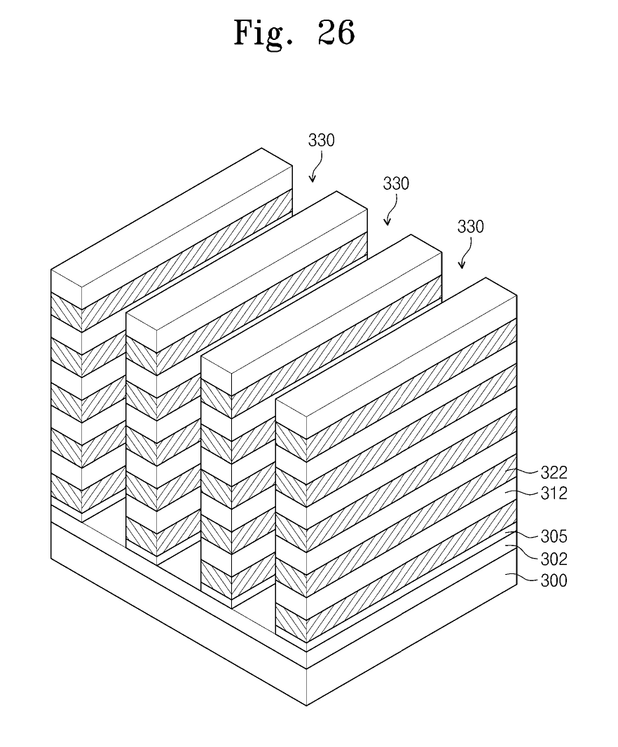

Referring to FIGS. 2 and 26, the thin film structure 315 may be patterned to form a plurality of through regions 330 exposing an upper surface of the semiconductor substrate 300 in operation S2. In patterning the thin film structure 315, the insulation films 310 and the conductive films 320 may be patterned to form insulation patterns 312 and gate patterns 322, respectively. For example, in forming the through regions 330, a mask pattern (not shown) defining two-dimensional positions of the through regions 330 may be formed on the thin film structure 315; and the thin film structure 315 may be anisotropically etched using the mask pattern as an etch mask. The through regions 330 may be formed two-dimensionally and regularly.

The through regions 330 may be trenches exposing the upper surface of the semiconductor substrate 300 and having a rectangular bottom surface, as illustrated in FIG. 26. Lines in a lowermost layer of the gate patterns 322 may be a ground selection line, and lines in an uppermost layer of the gate patterns 322 may be a string selection line.

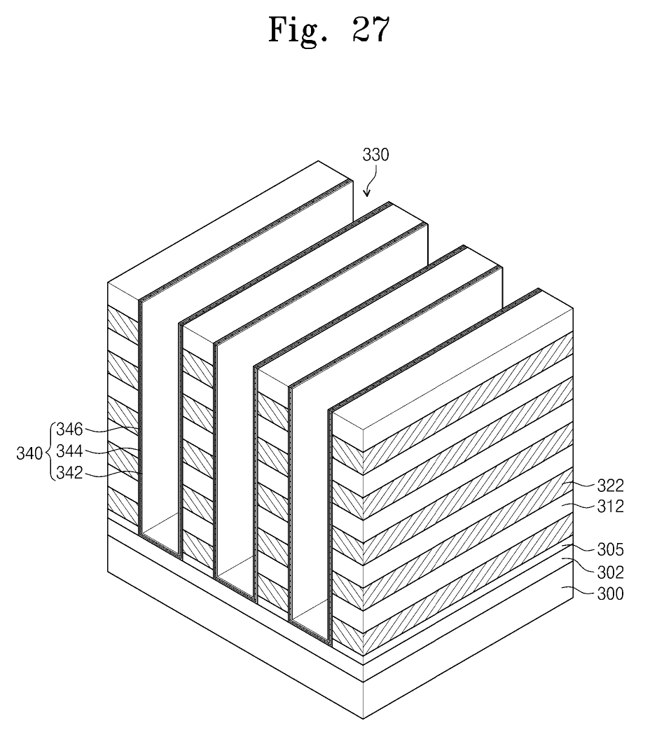

Referring to FIG. 27, an information storage film 340 (covering inner walls of the through regions 330) may be formed. The information storage film 340 may include a charge trap layer 344 having a charge trap site. The information storage film 340 may also include a blocking insulation film 342 (contacting the gate patterns 322) and a tunnel insulation film 346 where tunneling of charges occurs. The charge trap layer 344 may include, e.g., a silicon nitride film between the tunnel insulation film 346 and the blocking insulation film 342, the tunnel insulation film 346 may include, e.g., a silicon oxide film, and the blocking insulation film 342 may include, e.g., a high dielectric material film (e.g., aluminum oxide film or hafnium oxide film).

The information storage film 340 is not limited to a charge storage film as described above, and, in an implementation, may be a data storage thin film (e.g., a thin film for a variable resistance memory) based on another operation mechanism. In forming the information storage film 340, a preliminary information storage film (not illustrated) may be conformally formed on the semiconductor substrate 300 and inner walls of the through regions 330. Then, the preliminary information storage film covering the semiconductor substrate 300 may be partially etched using, as a mask, a spacer (not shown) covering the inner walls of the through regions 330. The spacer may be an insulation film and may be removed after forming the information storage film 340.

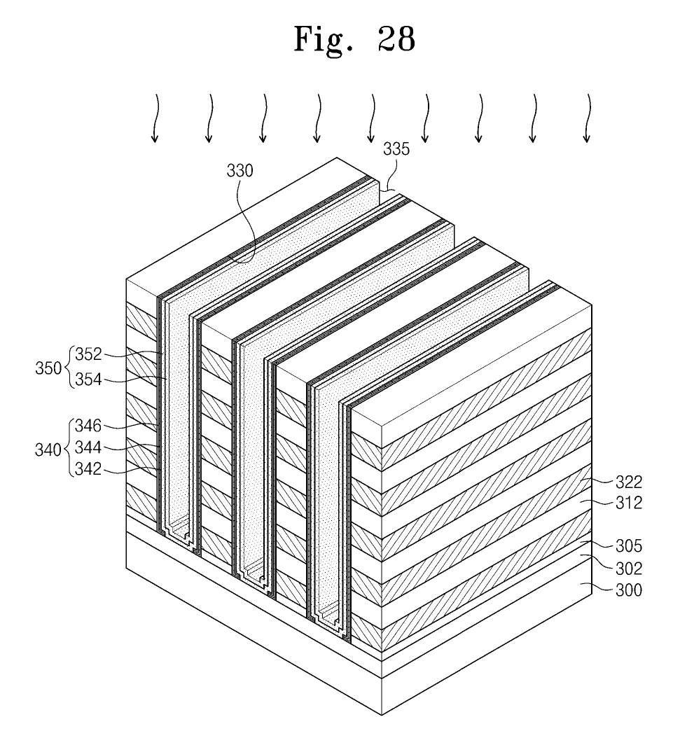

Referring to FIGS. 2 and 28, a first silicon film 352 (covering the through regions 330) may be formed in operation S3. A second silicon film 354 may be formed on the first silicon film 352 in operation S4. The first silicon film 352 and the second silicon film 354 may constitute a semiconductor film 350. The first silicon film 352 and the second silicon film 354 may define gap regions 335 within the through regions 330. The first silicon film 352 and the second silicon film 354 may be formed using different precursors, e.g., first and second precursors, respectively. A grain size of the first silicon film 352 may be greater than a grain size of the second silicon film 354.

The first silicon film 352 and the second silicon film 354 may be formed using a chemical vapor deposition method. The first silicon film 352 may be formed using a precursor of disilane (Si₂H₆), e.g., first precursor; and the second silicon film 354 may be formed using a precursor of silane (SiH₄), e.g., second precursor. The first silicon film 352 and the second silicon film 354 may be formed through a continuous in-situ process.

In forming the first silicon film 352, a first preliminary silicon film (not shown) may be formed using the disilane precursor; and a heat treatment process may be performed on the first preliminary silicon film to re-crystallize the first preliminary silicon film. Re-crystallizing the first preliminary silicon film may increase the grain size of the first silicon film 352. The heat treatment process may be performed by supplying nitrogen gas or water vapor, e.g., at an elevated temperature. The heat treatment process may be performed after the second silicon film 354 is formed. In an implementation, the heat treatment process may be performed as a wet oxidation process in which water vapor is supplied, e.g., at an elevated temperature.

As will be described in greater detail below, the first silicon film 352 and the second silicon film 354 may be channel regions of the semiconductor memory device. The first silicon film 352 (formed using the precursor of disilane (Si₂H₆)) may have a large grain size to ensure an excellent cell current characteristic. This may be due to the precursor of disilane (Si₂H₆) having two silicon atoms. Thus, nucleation and growth of an island seed may be facilitated. In an implementation, the first silicon film 352 may have a grain size of about 1 μm or greater.

The second silicon film 354 (formed using the precursor of silane (SiH₄)) may have excellent step coverage properties. Thus, even if the through regions 330 have a large aspect ratio, a uniform thin film may be formed. Excellent cell current ensured by the grain size of the first silicon film 352 may be complementary to the excellent step coverage properties ensured by the second silicon film 354.

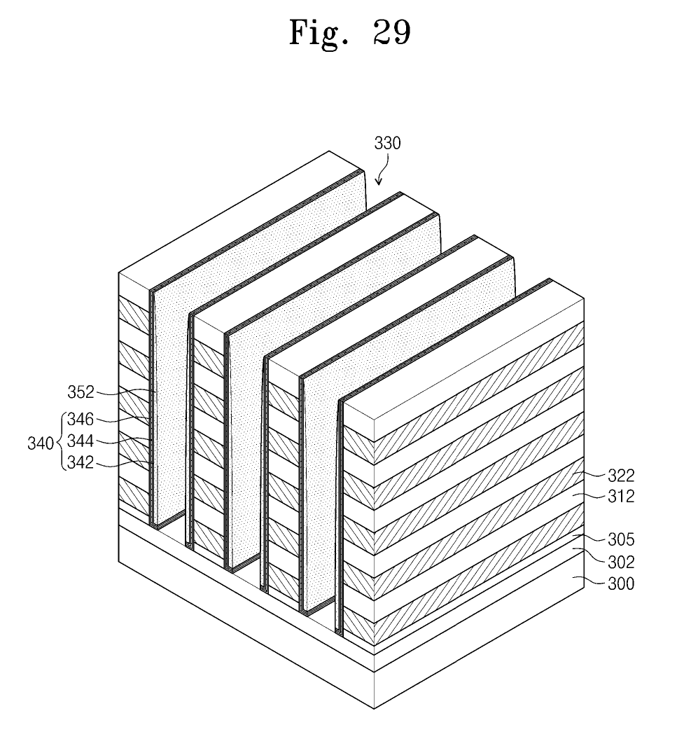

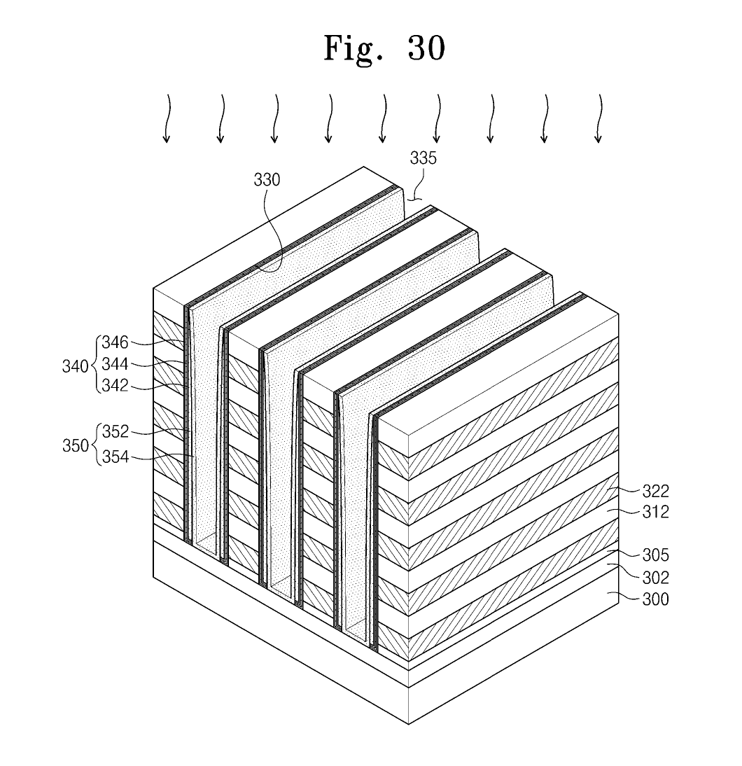

FIGS. 29 and 30 illustrate schematic views of modified stages in the method of forming the information storage film 340 using the first silicon film 352.

Referring to FIG. 29, in a different manner from that illustrated in FIG. 27, in forming the information storage film 340, a preliminary information storage film (not illustrated) may be conformally formed on inner walls of the through regions 330 and the semiconductor substrate 300, the first silicon film 352 may be formed on inner walls of the through regions 330, and a portion of the preliminary information storage film covering the semiconductor substrate 300 may be etched. In this case, the first silicon film 352 may be used as a mask for forming the information storage film 340 and may remain even after the information storage film 340 is formed.

Referring to FIG. 30, the second silicon film 354 may be formed on the first silicon film 352. The second silicon film 354 may cover the first silicon film 352 and exposed portions of the semiconductor substrate 300. After forming the second silicon film 354, a heat treatment process may be performed to re-crystallize the first silicon film 352.

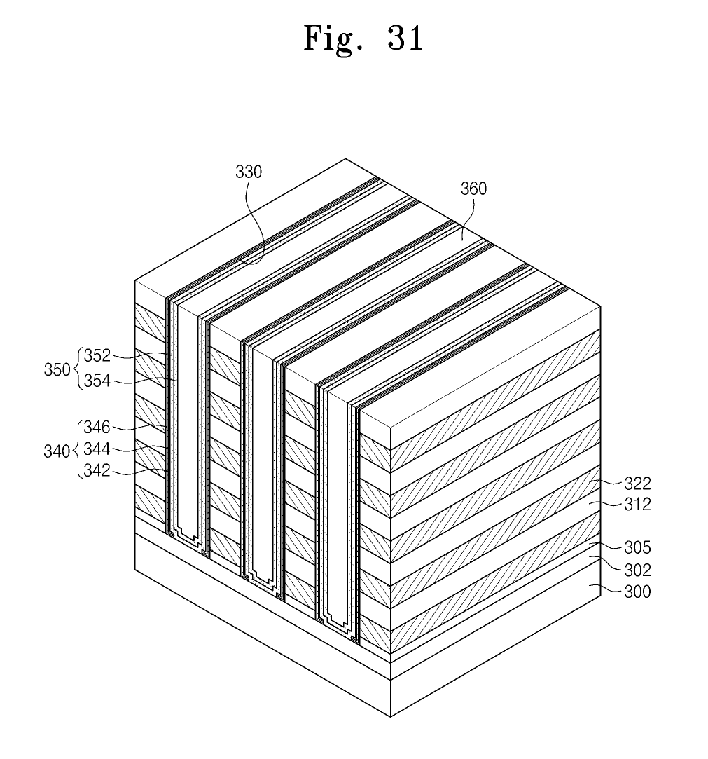

Referring to FIG. 31, a filling film 360 may be formed within the through regions 330. The filling film 360 may fill the gap regions 335. The filling film 360 may be formed by forming an insulation film (not illustrated) filling the gap regions 335 and by performing a planarization process on the insulation film. Alternatively, the first silicon film 352 and the second silicon film 354 may completely fill the through regions 330, and thus, in an implementation, the filling film 360 may be unnecessary and may be omitted.

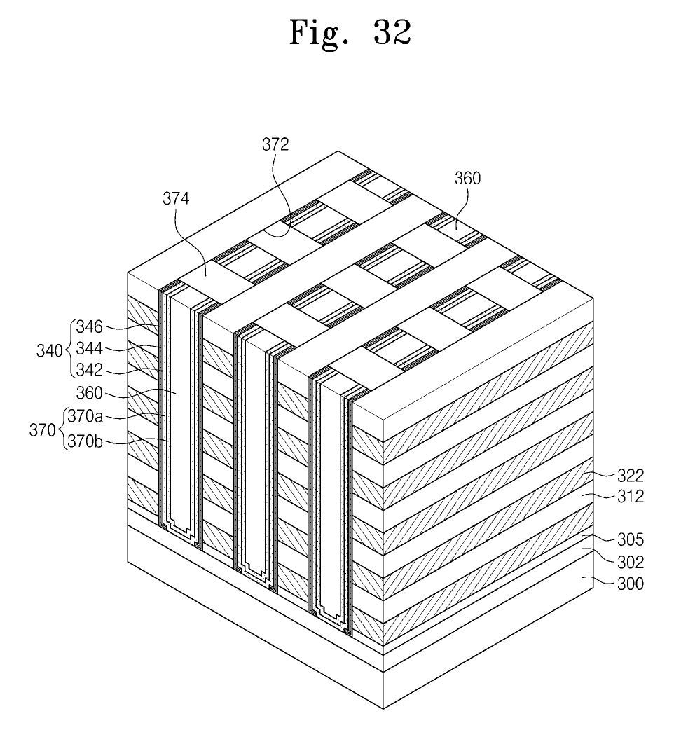

Referring to FIG. 32, the first silicon film 352 and the second silicon film 354 may be patterned to form semiconductor patterns 370 extending upwardly from the semiconductor substrate 100 within the through regions 330. The semiconductor patterns 370 may include first silicon patterns 370a (formed by patterning the first silicon film 352) and second silicon patterns 370b (formed by patterning the second silicon film 354). The semiconductor patterns 370 and the gate patterns 322 may constitute three-dimensionally arrayed transistors. In forming the semiconductor patterns 370, division regions 372 that divide the first silicon film 352 and the second silicon film 354 may be formed. The division regions 372 may be filled with a gap-fill insulation film 374. The gap-fill insulation film 374 may be, e.g., a silicon oxide film.

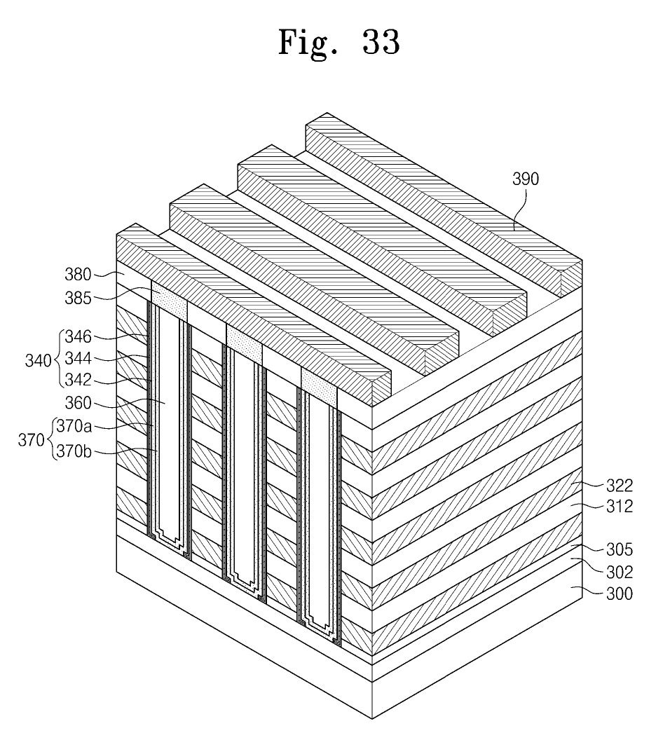

Referring to FIG. 33, an upper interlayer insulation film 380 covering the gap-fill insulation film 374 and the semiconductor patterns 370 may be formed. Contact plugs 385 (electrically connected to the semiconductor patterns 370) may be formed in the upper interlayer insulation film 380. Bit lines 390 (electrically connected to the contact plugs 385 and crossing the semiconductor patterns 322) may be formed.

According to the present embodiment, the semiconductor patterns 370 may be used as channels of transistors that are arrayed three-dimensionally. The semiconductor patterns 370 may include the first and second silicon patterns 370a and 370b so as to ensure an excellent cell current and excellent step coverage properties. Accordingly, the semiconductor patterns 370 may have excellent step coverage properties. Thus, transistors constituting a string may exhibit uniformity of cell current.

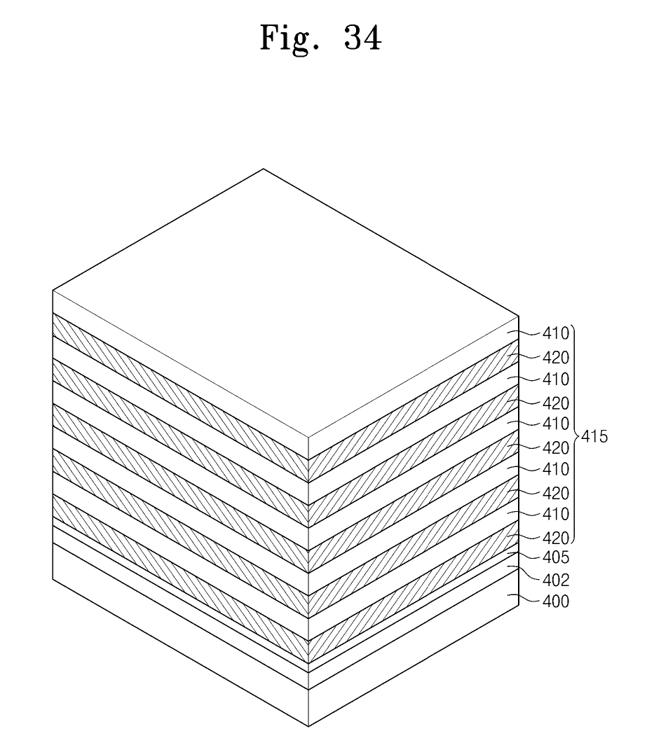

FIGS. 34 through 42 illustrate perspective views of stages in a method of forming a semiconductor memory device according to still another embodiment. Here, a repeated description of the same parts and/or steps as that of the previous embodiments will be omitted.

Referring to FIGS. 2 and 34, a thin film structure 415 including a plurality of thin films on a semiconductor substrate 400 may be formed in operation S1. The semiconductor substrate 400 may be formed of a single crystalline silicon. Alternatively, the semiconductor substrate 400 may be formed of a semiconductor material providing another semiconductor characteristic.

The thin film structure 415 may include insulation films 410 and conductive films 420, which may be sequentially and repeatedly, e.g., alternately, stacked. For example, the thin film structure 415 may include the insulation films 410 that are sequentially stacked, and the conductive films 420 between the insulation films 410. The insulation films 410 may be formed of, e.g., a silicon oxide or a silicon nitride. The conductive films 420 may be formed of, e.g., a metal or a polycrystalline silicon doped with impurities. A buffer insulation film 405 may be disposed between the semiconductor substrate 400 and the thin film structure 415. The buffer insulation film 405 may be formed of, e.g., a silicon oxide.

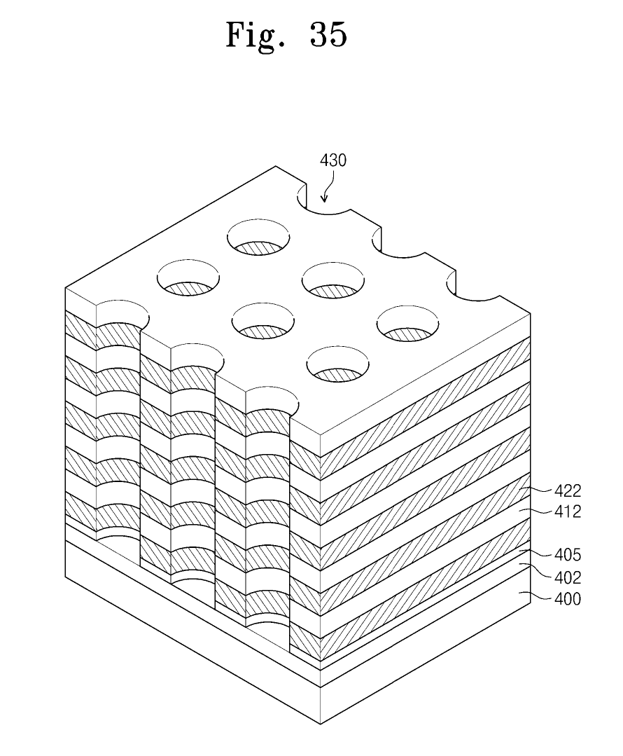

Referring to FIGS. 2 and 35, the thin film structure 415 may be patterned to form a plurality of through regions 430 exposing an upper surface of the semiconductor substrate 400 in operation S2. In patterning the thin film structure 415, the insulation films 410 and the conductive films 420 may be patterned to form insulation patterns 412 and gate patterns 422. For example, in forming the through regions 430, a mask pattern (not shown) defining two-dimensional positions of the through regions 430 may be formed on the thin film structure 415; and the thin film structure 415 may be anisotropically etched using the mask pattern as an etch mask. The through regions 430 may be formed two-dimensionally and regularly.

The through regions 430 may have hole shapes exposing the upper surface of the semiconductor substrate 400 and may have a circular bottom surface, as illustrated in FIG. 35. Lines disposed in a lowermost layer of the gate patterns 422 may be used as a ground selection line.

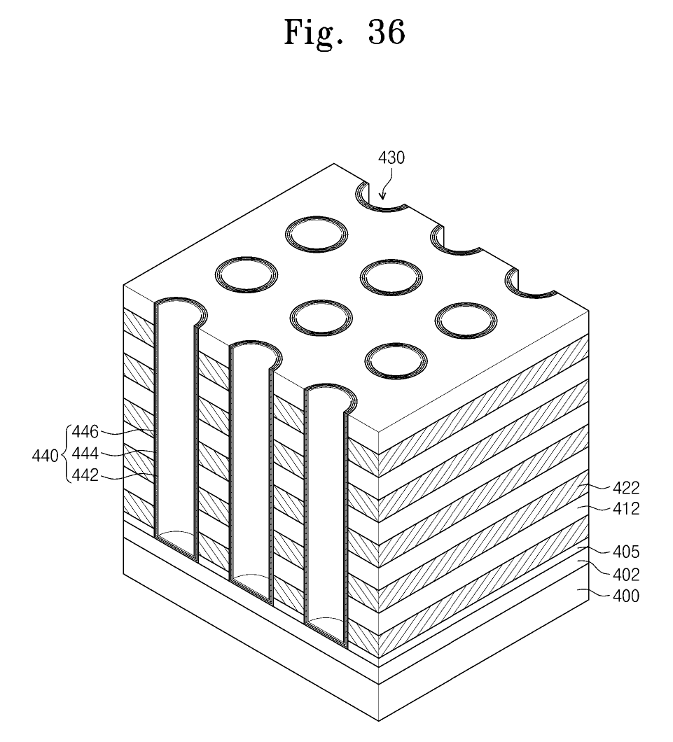

Referring to FIG. 36, an information storage film 440 (covering inner walls of the through regions 430) may be formed. The information storage film 440 may include a charge trap layer 444 having a charge trap site. The information storage film 440 may also include a blocking insulation film 442 (contacting the gate patterns 422) and a tunnel insulation film 446 where tunneling of a charge occurs. The charge trap layer 444 may include a silicon nitride film and may be formed between the tunnel insulation film 446 and the blocking insulation film 442. The tunnel insulation film 446 may include, e.g., a silicon oxide film. The blocking insulation film 442 may include a high dielectric material film (e.g., aluminum oxide film or hafnium oxide film).

The information storage film 440 is not limited to a charge storage film as described above, and, in an implementation, may be a data storage thin film (e.g., a thin film for a variable resistance memory) based on another operation mechanism. In forming the information storage film 440, a preliminary information storage film (not illustrated) may be conformally formed on the semiconductor substrate 400 and inner walls of the through regions 430. Then, the preliminary information storage film covering the semiconductor substrate 400 may be partially etched using, as a mask, a spacer (not shown) covering the inner walls of the through regions 430. The spacer may be formed as an insulation film and may be removed after forming the information storage film 440.

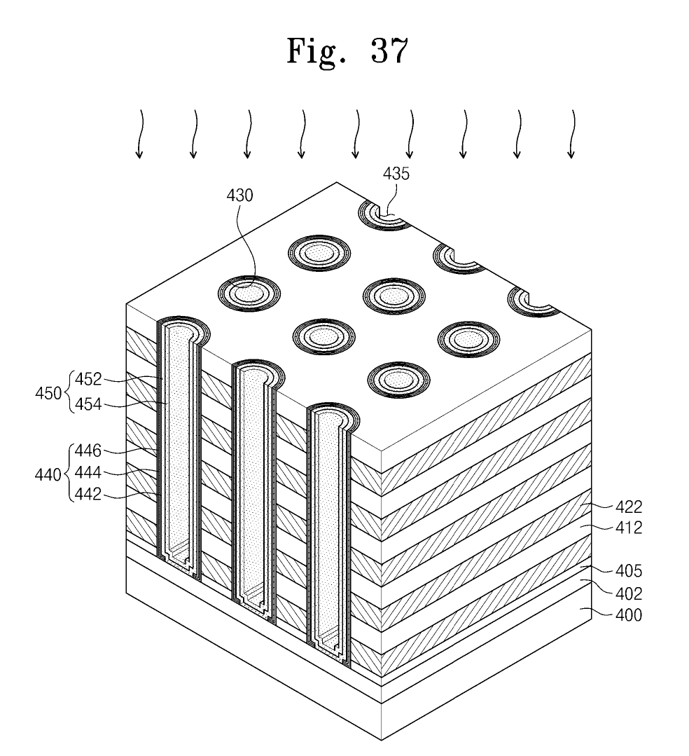

Referring to FIGS. 2 and 37, a first silicon film 452 covering the through regions 430 may be formed in operation S3. A second silicon film 454 may be formed on the first silicon film 452 in operation S4. The first silicon film 452 and the second silicon film 454 may constitute a semiconductor film 450. The first silicon film 452 and the second silicon film 454 may define gap regions 435 within the through regions 430. The first silicon film 452 and the second silicon film 454 may be formed using different precursors. A grain size of the first silicon film 452 may be greater than a grain size of the second silicon film 454.

The first silicon film 452 and the second silicon film 454 may be formed using a chemical vapor deposition method. The first silicon film 452 may be formed using a precursor of disilane (Si₂H₆), e.g., first precursor; and the second silicon film 454 may be formed using a precursor of silane (SiH₄), e.g., second precursor. The first silicon film 452 and the second silicon film 454 may be formed through a continuous in-situ process.

In forming the first silicon film 452, a first preliminary silicon film (not shown) may be formed using the disilane precursor and a heat treatment process may be performed on the first preliminary silicon film to re-crystallize the first preliminary silicon film. Re-crystallizing the first preliminary silicon film may increase the grain size of the first silicon film 452. The heat treatment process may be performed by supplying nitrogen gas or water vapor, e.g., at an elevated temperature. In an implementation, the heat treatment process may be performed after the second silicon film 454 is performed. The heat treatment process may be performed as a wet oxidation process in which water vapor is supplied, e.g., at an elevated temperature.

As will be described in greater detail below, the first silicon film 452 and the second silicon film 454 may be channel regions of the semiconductor memory device. The first silicon film 452 (formed using the precursor of disilane (Si₂H₆)) may have a large grain size to ensure excellent cell current characteristics. This may be due to the precursor of disilane (Si₂H₆) having two silicon atoms. Thus, nucleation and growth of an island seed may be facilitated. In an implementation, the first silicon film 452 may have a grain size of about 1 μm or greater.

The second silicon film 454 (formed using the precursor of silane (SiH₄)) may have excellent step coverage properties. Thus, even if the through regions 430 have a large aspect ratio, a uniform thin film may be formed. Excellent cell current ensured by the grain size of the first silicon film 454 may be complementary to excellent step coverage properties ensured by the second silicon film 454.

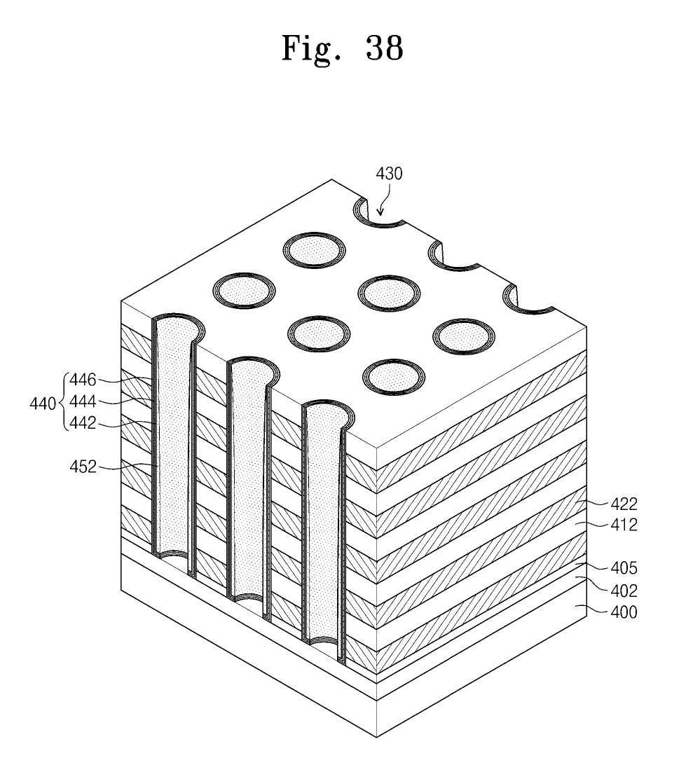

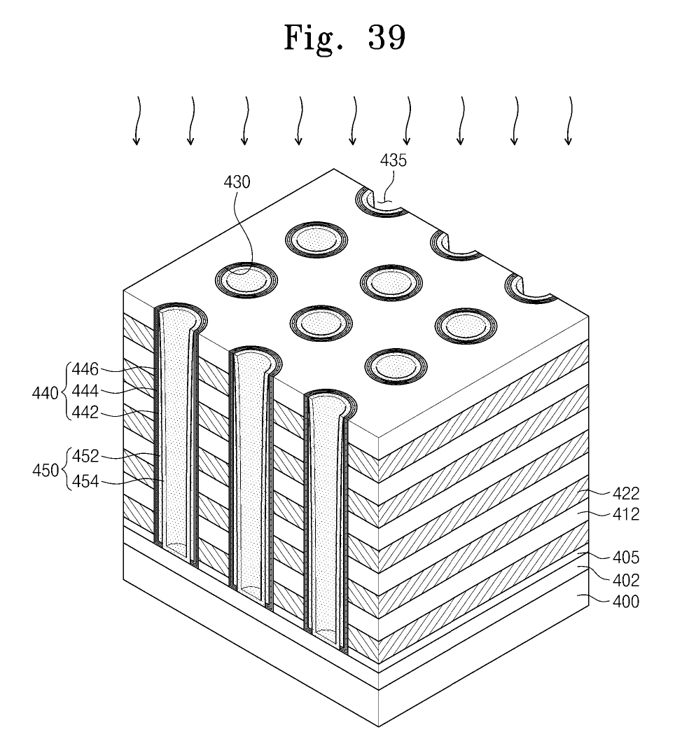

FIGS. 38 and 39 illustrate perspective views of modified steps of forming the information storage film 440 formed using the first silicon film 452.

Referring to FIG. 38, in a different manner from that illustrated in FIG. 36, in forming the information storage film 440, a preliminary information storage film (not illustrated) may be conformally formed on inner walls of the through regions 430 and on the semiconductor substrate 400. The first silicon film 452 may be formed on the inner walls of the through regions 430; and a portion of the preliminary information storage film covering the semiconductor substrate 400 may be etched. In this case, the first silicon film 452 may be used as a mask for forming the information storage film 440 and may remain even after the information storage film 440 is formed.

Referring to FIG. 39, the second silicon film 454 may be formed on the first silicon film 452. The second silicon film 454 may cover the first silicon film 452 and exposed portions of the semiconductor substrate 400. After forming the second silicon film 454, a heat treatment process may be performed to re-crystallize the first silicon film 452.

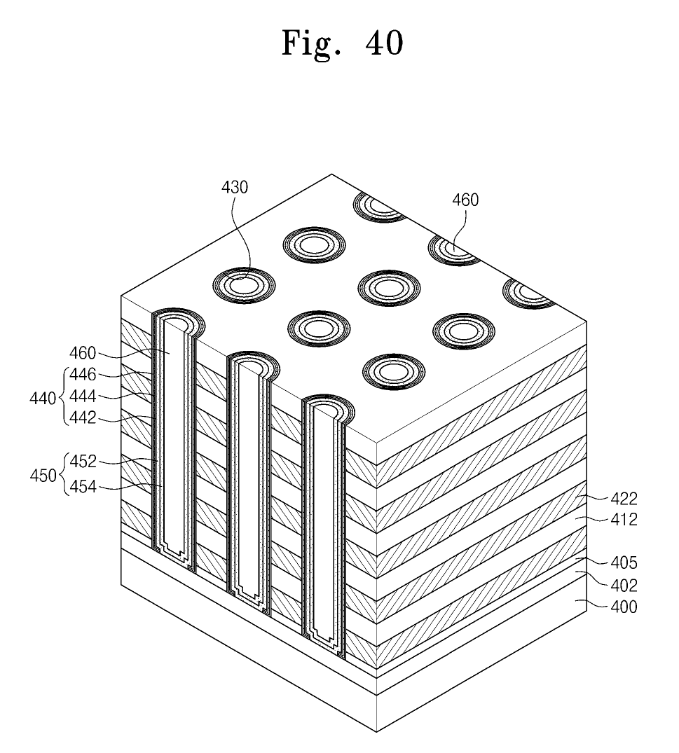

Referring to FIG. 40, a filling film 460 may be formed within the through regions 430. The filling film 460 may fill the gap regions 435. The filling film 460 may be formed by forming an insulation film (not illustrated) filling the gap regions 435 and by performing a planarization process on the insulation film. Alternatively, the first silicon film 452 and the second silicon film 454 may be completely fill the through regions 430, and thus, the filling film 460 may be unnecessary and may be omitted.

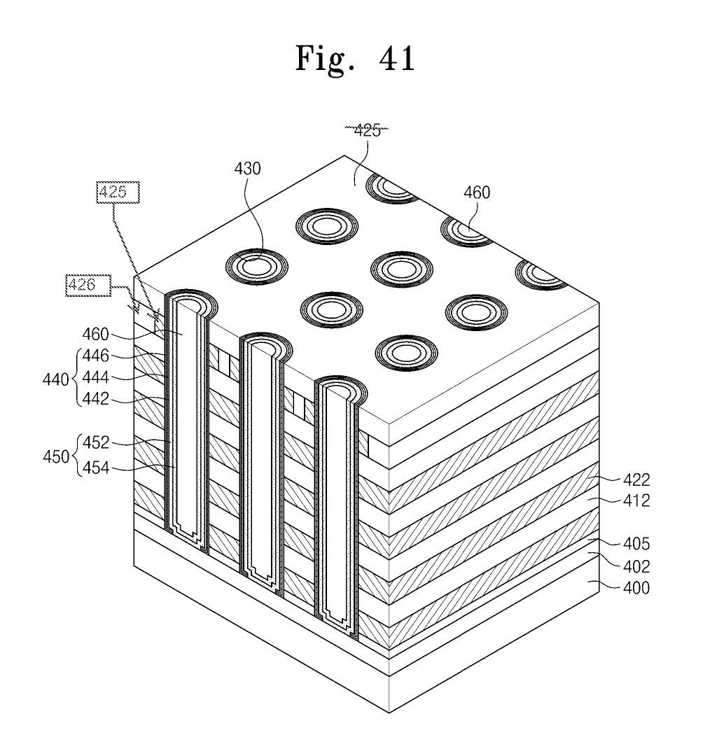

Referring to FIG. 41, the gate pattern 422 in an uppermost layer may be patterned to form string selection lines 425. The string selection lines 425 may extend in a direction crossing the semiconductor film 450. After forming the string selection lines 425, an insulation film 426 may be formed between the string selection lines 425.

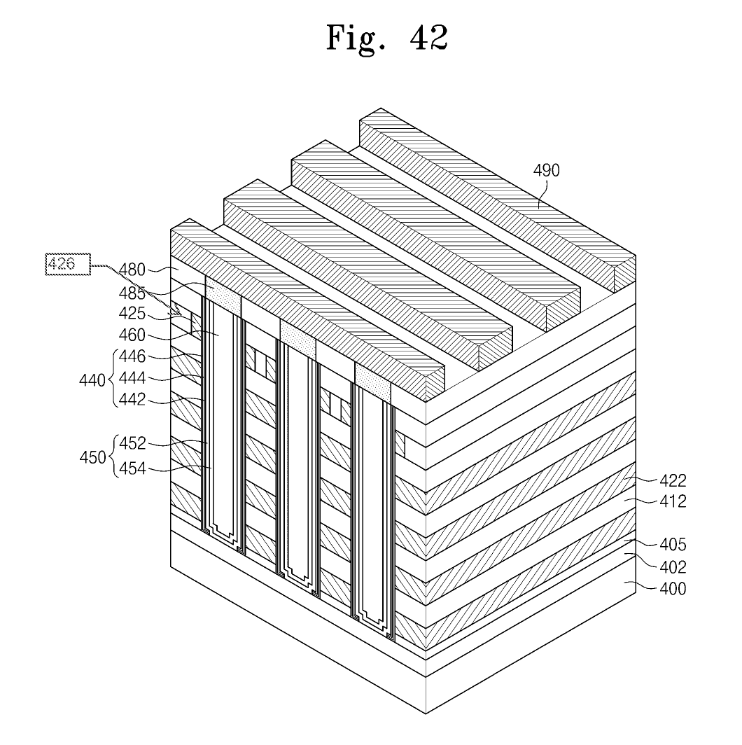

Referring to FIG. 42, an upper interlayer insulation film covering the semiconductor film 450 may be formed. Contact plugs 485 (that are electrically connected to the semiconductor film 450) may be formed in the upper interlayer insulation film 480. Bit lines 490 (which may be electrically connected to the contact plugs 485 and may cross the string selection lines 425) may be formed.

According to the present embodiment, the semiconductor film 450 may be channels of transistors that are arrayed three-dimensionally. The semiconductor film 450 may include the first and second silicon films 452 and 454 so as to ensure an excellent cell current and excellent step coverage properties. Thus, transistors constituting a string may exhibit uniformity of cell current.

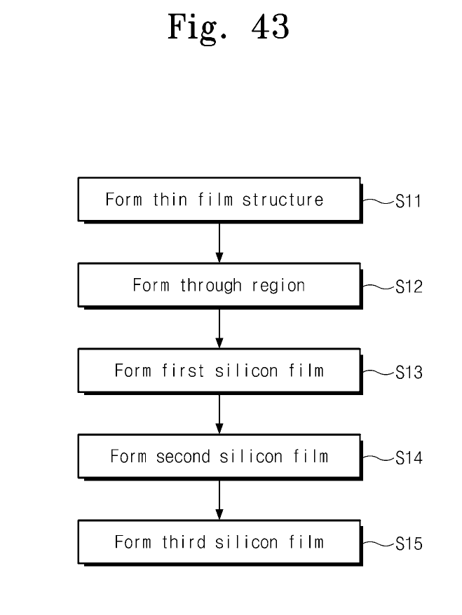

FIG. 43 illustrates a flowchart describing a method of forming a semiconductor memory device according to another embodiment.

Referring to FIG. 43, a thin film structure including a plurality of thin films may be formed on a semiconductor substrate in operation S11. The thin film structure may be patterned to form through regions in the thin film structure in operation S12. Then, a first silicon film covering the through regions may be formed in operation S13. A second silicon film may be formed on the first silicon film in operation S14. The first silicon film and the second silicon film may be formed using different precursors. A third silicon film may be formed on the second silicon film in operation S15. A grain size of the first silicon film may be greater than a grain size of the second silicon film.

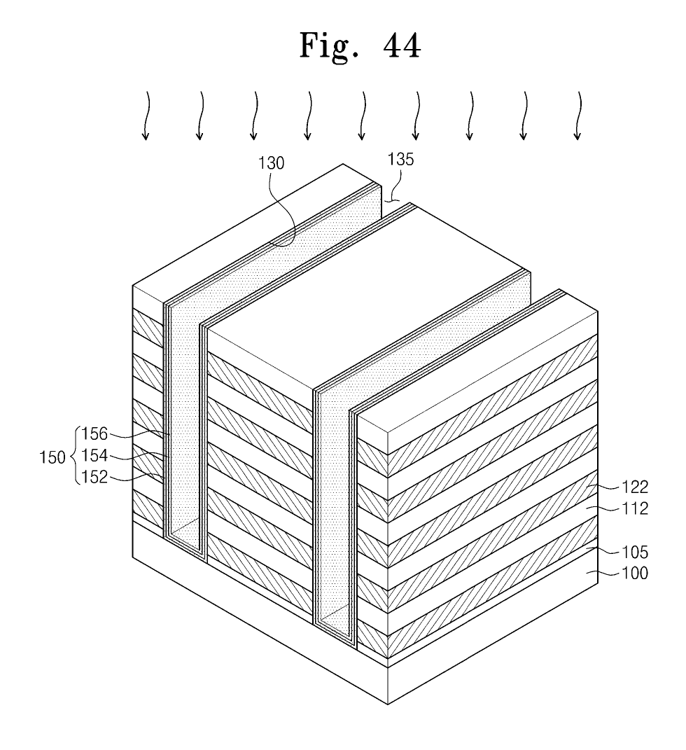

FIG. 44 illustrates a perspective view showing a modification of the method described with reference to FIG. 5. Here, a repeated description of the same parts and/or steps as that of the previous embodiment will be omitted.

Referring to FIGS. 43 and 44, the first silicon film 152 covering the through regions 130 may be formed in operation S13. The second silicon film 154 may be formed on the first silicon film 152 in operation S14. A third silicon film 156 may be formed on the second silicon film 154. The first, second, and third silicon films 152, 154, and 156 may constitute the semiconductor film 150 in a different manner from that of the previous embodiments. The first silicon film 152 and the second silicon film 154 may be formed using different precursors, e.g., first and second precursors, respectively. A grain size of the first silicon film 152 may be greater than that of the second silicon film 154.

The first silicon film 152 and the second silicon film 154 may be formed using a chemical vapor deposition method. The first silicon film 152 may be formed using a precursor of disilane (Si₂H₆), e.g., first precursor; and the second silicon film 154 may be formed using a precursor of silane (SiH₄), e.g., second precursor. The first silicon film 152 and the second silicon film 154 may be formed through a continuous in-situ process.

In forming the first silicon film 152, a first preliminary silicon film (not shown) may be formed using the disilane precursor; and then a heat treatment process may be performed on the first preliminary silicon film to re-crystallize the first preliminary silicon film. Re-crystallizing of the first preliminary silicon film may increase the grain size of the first silicon film 152. The heat treatment process may be performed by supplying nitrogen gas or water vapor, e.g., at an elevated temperature. The heat treatment process may be performed after the second or third silicon film 154 or 156 is formed. In an implementation heat treatment process may be performed as a wet oxidation process in which water vapor is supplied, e.g., at an elevated temperature.

The first, second, and third silicon films 152, 154, and 156 may be channel regions of a semiconductor memory device. The first silicon film 152 (formed using the precursor of disilane (Si₂H₆)) may have a large grain size to ensure an excellent cell current characteristic. This may be due to the precursor of disilane (Si₂H₆) having two silicon atoms. Thus, nucleation and growth of an island seed may be facilitated. In an implementation, the first silicon film 152 may have a grain size of about 1 μm or greater. A grain boundary may degrade mobility of electric charges. Thus, as a grain size increases, density of a grain boundary decreases, and a resistance value may decrease.

The second silicon film 154 (formed using the precursor of silane (SiH₄)) may have excellent step coverage properties. Thus, even if the through regions 130 have a large aspect ratio (e.g., about 50 or greater), a uniform thin film may be formed. Excellent cell current ensured by the grain size of the first silicon film 152 may be complementary to excellent step coverage properties ensured by the second silicon film 154.

The third silicon film 156 may be formed using a disilane precursor and a silane precursor. Thus, an excellent cell current characteristic and excellent step coverage properties may be ensured. For example, the third silicon film 156 may be formed by simultaneously supplying disilane gas and silane gas.

In a manner different from the modification of the previous embodiments, referring to FIG. 44, the first silicon film 152 may be formed using a precursor of trisilane (Si₃H₈) in operation S13; and the second silicon film 154 may be formed using a precursor of silane (SiH₄) in operation S14, e.g., the trisilane has three silicon atoms. Thus, nucleation and growth of an island seed may be facilitated. The third silicon film 156 may be formed using a trisilane precursor and a silane precursor in operation S15. The third silicon film 156 may be formed by simultaneously supplying trisilane gas and silane gas.

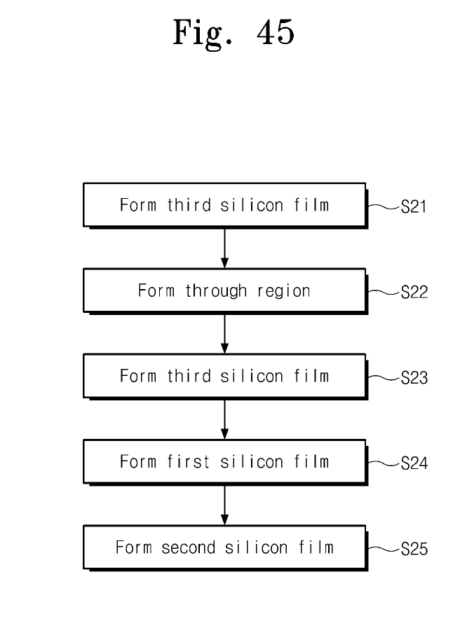

FIG. 45 illustrates a flowchart describing a method of forming a semiconductor memory device according to yet another embodiment. Here, a repeated description of the same parts and/or steps as those of the previous embodiments and the modifications thereof will be omitted.

Referring to FIG. 45, a thin film structure including a plurality of thin films may be formed on a semiconductor substrate in operation S21. The thin film structure may be patterned to form through regions in the thin film structure in operation S22. Then, a third silicon film covering the through regions may be formed in operation S23. A first silicon film may be formed on the third silicon film in operation S24. A second silicon film may be formed on the first silicon film in operation S25. The first silicon film and the second silicon film may be formed using different precursors, e.g., a first and second precursor, respectively. A grain size of the first silicon film may be greater than a grain size of the second silicon film.

A grain size of the third silicon film may be greater than the grain size of the first silicon film; and, as described above, the grain size of the first silicon film may be greater than the grain size of the second silicon film.

The third silicon film may be formed using a precursor of trisilane (Si₃H₈), the first silicon film may be formed using a precursor of disilane (Si₂H₆), e.g., first precursor, and the second silicon film may be formed using a precursor of silane (SiH₄), e.g., second precursor. A semiconductor pattern including the first, second, and third silicon films may have an excellent cell current characteristic and an excellent step coverage properties.

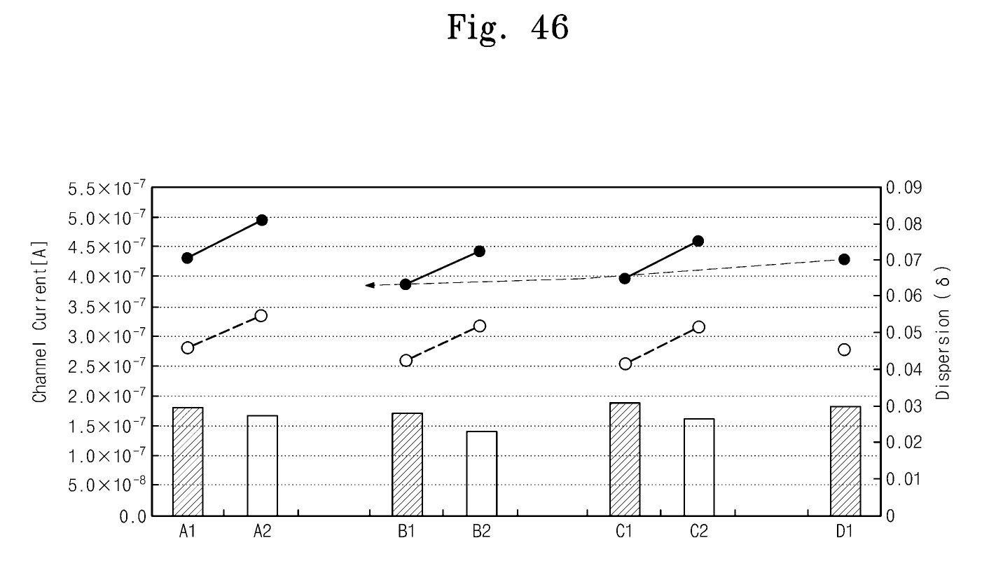

FIG. 46 illustrates a graph showing channel current characteristics of semiconductor memory devices according to the embodiments. In FIG. 46, ‘--’ denotes a mean channel current, and ‘-∘-’ denotes a minimum channel current. Dispersion is denoted by and ‘ [symbol] ’ and ‘□’.

In FIG. 46, A1 and A2 represent cases where silicon films having a thickness of about 300 Å were formed using a silane precursor. A heat treatment process was performed in the case A2; and a heat treatment process was not performed in the case A1. Here, the heat treatment process was an oxidation process. B1 and B2 represent cases where first silicon films having a thickness of about 120 Å were formed using a disilane precursor and second silicon films having a thickness of about 80 Å were formed using a silane precursor. A heat treatment process was performed in the case B2; and a heat treatment process was not performed in the case B1. C1 and C2 represent cases where first silicon films having a thickness of about 150 Å were formed using a disilane precursor and second silicon films having a thickness of about 70 Å were formed using a silane precursor. A heat treatment process was performed in the case C2; and a heat treatment process was not performed in the case C1. D1 represents a case where a first silicon film having a thickness of about 200 Å was formed using a disilane precursor and a second silicon film having a thickness of about 50 Å was formed using a silane precursor. Although entire thicknesses of specimens may be different, total thicknesses of the first and second silicon films formed on side walls of through regions may be substantially the same according to the embodiments.

Referring to FIG. 46, as the thickness of the first silicon film formed using the disilane precursor increased, a mean channel current and a minimum channel current increased. This may be because the first silicon film had a large grain size. In addition, a cell current was greater in the case in which the heat treatment process was performed than in the case in which the heat treatment process was not performed. This may be because a grain size was increased by re-crystallization of the first silicon film.

In addition, when the heat treatment process was performed, as the grain size increased by the re-crystallization of the first silicon film, dispersion decreased, thereby ensuring uniformity of a semiconductor memory device.

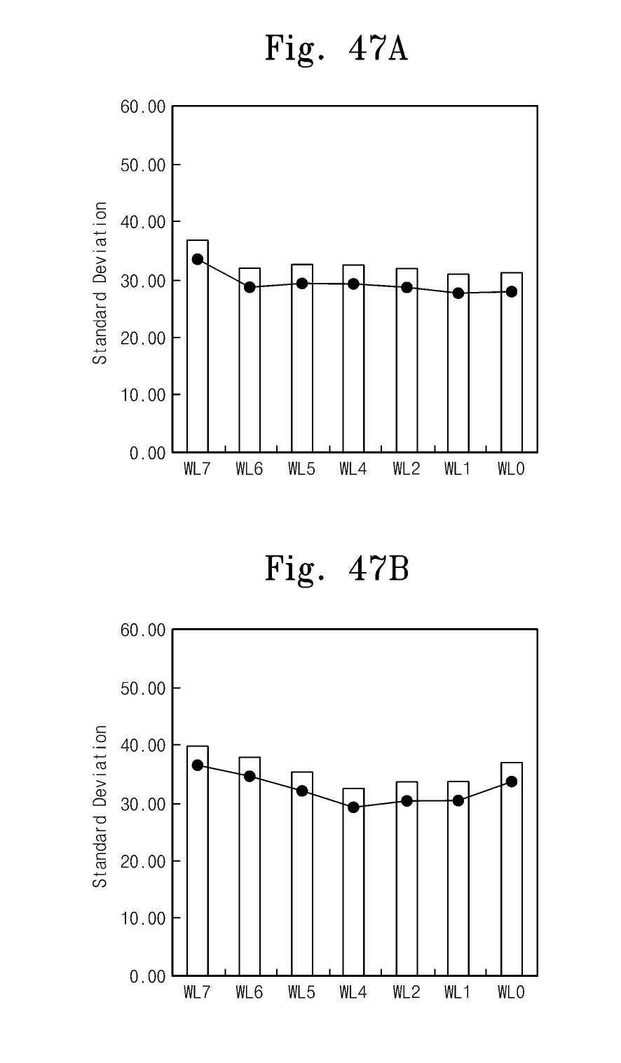

FIGS. 47A through 47D illustrate graphs showing standard deviations of channel currents with respect to gate lines according to embodiments. The gate lines are denoted by WL0 to WL7. The closest gate line to a semiconductor substrate is denoted by WL0; and the farthest gate line from the semiconductor substrate is denoted by WL7.

FIG. 47A illustrates a graph showing a case where a silicon film having a thickness of about 300 Å was formed using a disilane precursor. FIG. 47B illustrates a graph showing a case where a first silicon film having a thickness of about 200 Å was formed using a disilane precursor and a second silicon film having a thickness of about 50 Å was formed using a silane precursor. FIG. 47C illustrates a graph showing a case where a first silicon film having a thickness of about 150 Å was formed using a disilane precursor and a second silicon film having a thickness of about 70 Å was formed using a silane precursor. FIG. 47D illustrates a graph showing a case where a first silicon film having a thickness of about 120 Å was formed using a disilane precursor and a second silicon film having a thickness of about 80 Å was formed using a silane precursor. Although the entire thicknesses of specimens may be different, total thicknesses of first and second silicon films formed on the side walls of through regions may be substantially the same according to the embodiment.

Referring to FIGS. 47A through 47D, as the second silicon film using the silane precursor increased, step coverage properties were improved to thereby decrease a standard deviation between gate lines. Thus, the second silicon film using the silane precursor ensured uniformity between the gate lines (word lines).

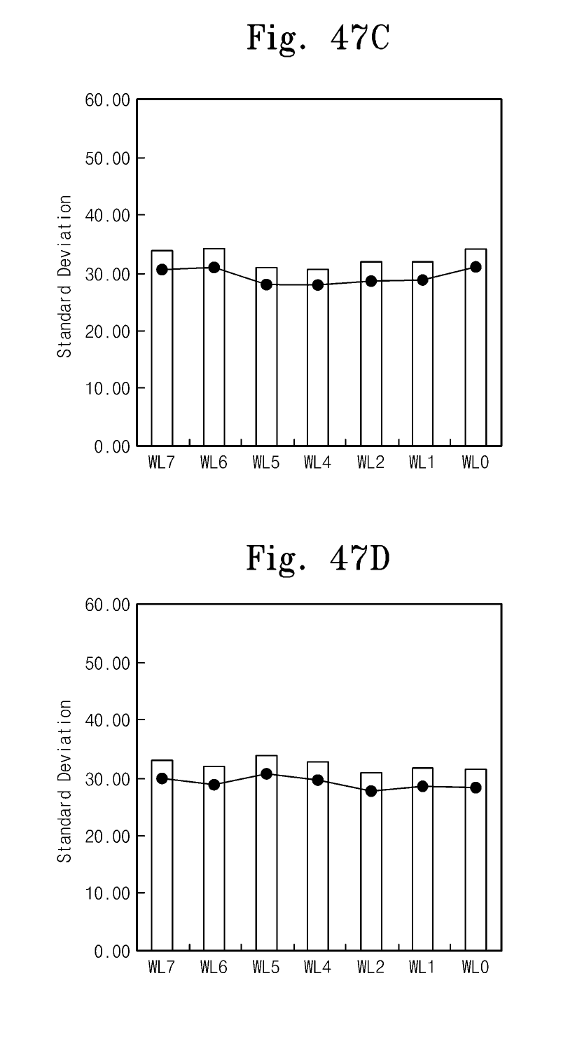

FIGS. 48 through 50 illustrate schematic sectional views showing stages in a method of forming a semiconductor memory device according to still another embodiment.

Referring to FIG. 48, a thin film structure 505 including a plurality of thin films on a semiconductor substrate 500 may be formed. The thin film structure 505 may include a first insulation film 510 on the semiconductor substrate 500, storage node contacts 520 in the first insulation film 510, an etch stopper 530 on the first insulation film 510, and a mold oxidation film 540 on the etch stopper 530. The first insulation film 510 may be formed of, e.g., a silicon oxide. The storage node contacts 520 may be formed of, e.g., a conductive material. The etch stopper 530 may be formed of, e.g., a silicon nitride. The mold oxidation film 540 and the first insulation film 510 may be formed of the same material.

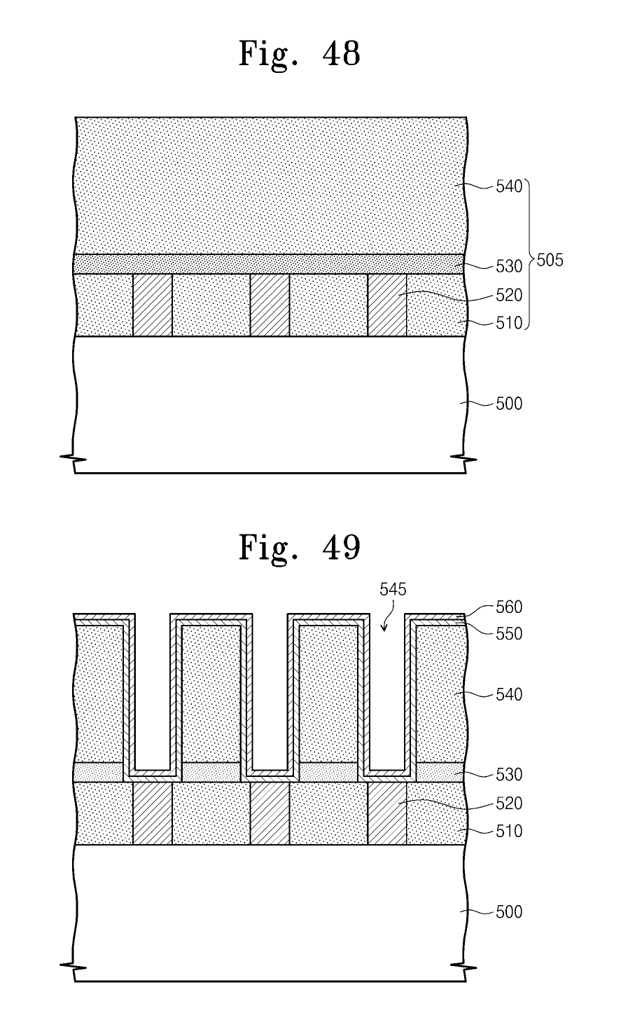

Referring to FIG. 49, the thin film structure 505 may be patterned to form a plurality of through regions 545. For example, first, the mold oxidation film 540 may be patterned to expose an upper surface of the etch stopper 530; and the etch stopper 530 may be etched to expose the storage node contacts 520.

A first silicon film 550 (covering the through regions 545) may be formed. A second silicon film 560 may be formed on the first silicon film 550. The first silicon film 550 and the second silicon film 560 may be formed using different precursors, e.g., first and second precursors, respectively. A grain size of the first silicon film 550 may be greater than a grain size of the second silicon film 560.

The first silicon film 550 and the second silicon film 560 may be formed using a chemical vapor deposition method. The first silicon film 550 may be formed using a precursor of disilane (Si₂H₆), e.g., first precursor; and the second silicon film 560 may be formed using a precursor of silane (SiH₄), e.g., second precursor. The first silicon film 550 and the second silicon film 560 may be formed through a continuous in-situ process.

In forming the first silicon film 550, a first preliminary silicon film (not shown) may be formed using the disilane precursor and a heat treatment process may then be performed on the first preliminary silicon film to re-crystallize the first preliminary silicon film. Re-crystallizing the first preliminary silicon film may increase the grain size of the first silicon film 550. The heat treatment process may be performed by supplying nitrogen gas or water vapor, e.g., at an elevated temperature. The heat treatment process may be performed after the second silicon film 560 is formed. The heat treatment process may be performed as a wet oxidation process in which water vapor is supplied, e.g., at an elevated temperature.

The first silicon film 550 (formed using the precursor of disilane (Si₂H₆)) may have a large grain size to ensure excellent conductivity. This may be because the precursor of disilane (Si₂H₆) has two silicon atoms. Thus, nucleation and growth of an island seed may be facilitated. In an implementation, the first silicon film 552 may have a grain size of about 1 μm or greater. A grain boundary may degrade mobility of electric charges. Thus, as a grain size increases, the density of a grain boundary decreases, and a resistance value may decrease.

The second silicon film 560 (formed using the precursor of silane (SiH₄)) may have excellent step coverage properties. Thus, even if the through regions 545 have a large aspect ratio, a uniform thin film may be formed. Excellent conductivity ensured by the grain size of the first silicon film 550 may be complementary to excellent step coverage properties ensured by the second silicon film 560.

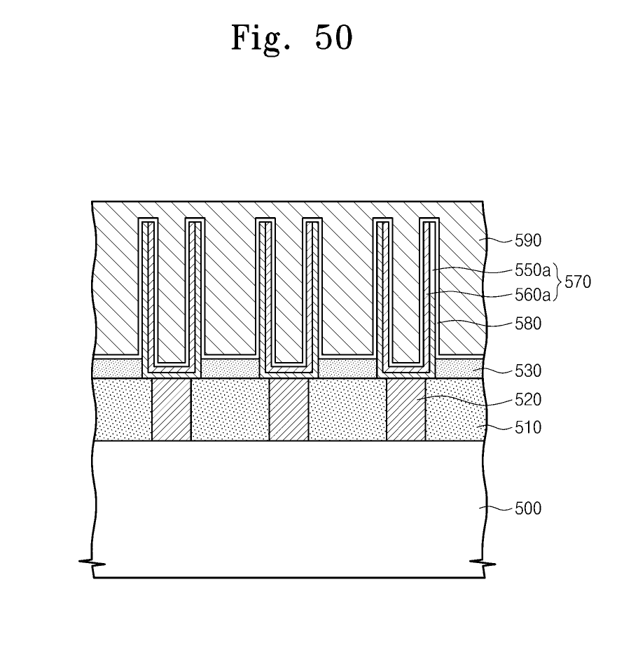

Referring to FIG. 50, a sacrificial oxide film (not shown) may be formed within the through regions 545 (provided with the first and second silicon films 550 and 560). Then, a planarization process may be performed on the sacrificial oxide film to expose an upper surface of the mold oxidation film 540. Then, the mold oxidation film 540 and the sacrificial oxide film may be removed to form lower electrodes 570. The lower electrodes 570 may include a first silicon pattern 550a (formed by patterning the first silicon film 550) and a second silicon pattern 560a (formed by patterning the second silicon film 560). A dielectric film 580 (covering the lower electrodes 570 and the etch stopper 530) may be formed. The dielectric film 580 may be formed of a material having a high dielectric constant, e.g., a tantalum oxide. A plate electrode 590 (covering the dielectric film 580) may be formed. The plate electrode 590 may be formed of a conductive material, e.g., a titanium nitride.

As described according to the embodiment of FIGS. 48 through 50, the lower electrodes having excellent conductivity and excellent step coverage properties may be formed in the through regions having a large aspect ratio. A DRAM memory device is exemplified in the embodiment of FIGS. 48 to 50, but the embodiments are not limited thereto, and semiconductor films formed in through regions of other semiconductor devices may be formed. For example, according to an embodiment, a semiconductor film filling a contact hole having a large aspect ratio can be formed.

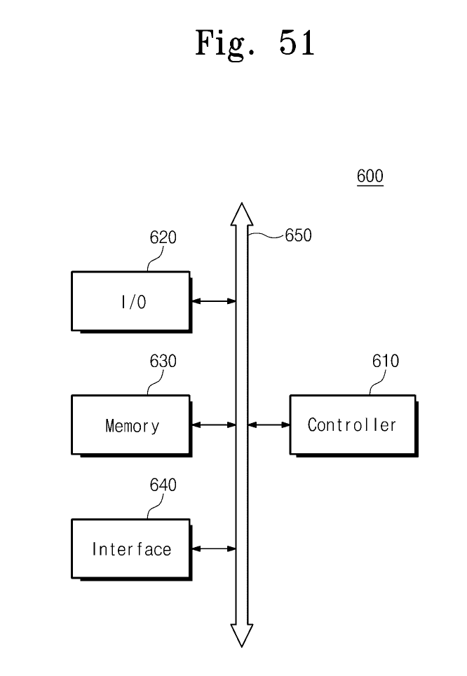

FIG. 51 illustrates a block diagram showing a memory system including a semiconductor memory device formed according to an embodiment.

Referring to FIG. 51, a memory system 600 may be applied to or used in, e.g., a personal digital assistant (PDA), a portable computer, a web tablet, a wireless phone, a mobile phone, a digital music player, a memory card, or all kinds of devices for transmitting and/or receiving information via a wireless environment.

The memory system 600 may include a controller 610, an input/output device 620, e.g., a keypad, a keyboard, and/or a display, a memory 630, an interface 640, and a bus 650. The memory 630 may communicate with the interface 640 through the bus 650.

The controller 610 may include at least one microprocessor, a digital signal processor, a microcontroller, or other process devices similar thereto. The memory 630 may be used to store commands executed by the controller 610. The input/output device 620 may receive external data or signals from outside of the system 600 or may output data or signals outside of the system 600. For example, the input/output device 620 may include a keyboard, a keypad, or a display device.

The memory 630 may include a semiconductor memory device according to an embodiment. The memory 630 may further include other kinds of memories, e.g., a volatile memory for arbitrarily irregular access. The interface 640 may transmit data into a communication network or may receive data from a communication network.

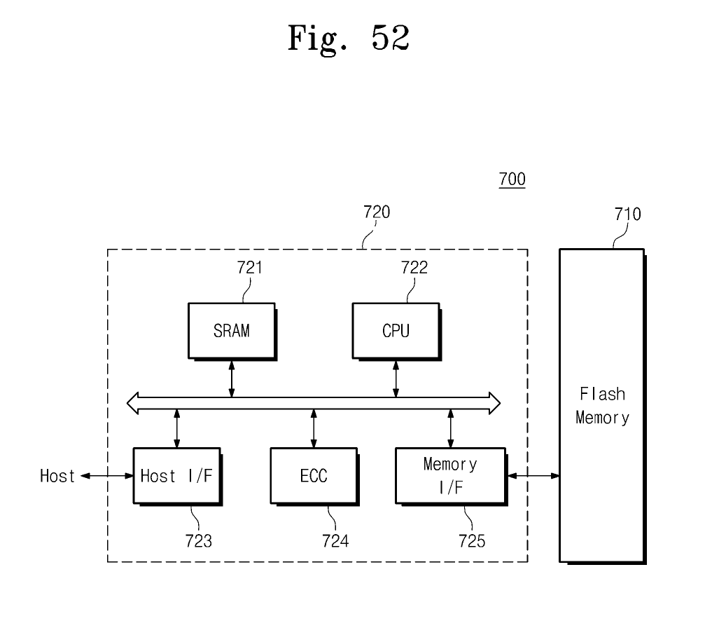

FIG. 52 illustrates a block diagram showing a memory card including a semiconductor memory device formed according to an embodiment.

Referring to FIG. 52, a memory card 700 f (or supporting high-capacity data storage) may include a flash memory device 710. The memory card 700 may include a memory controller 720 for controlling various data exchanges between a host and the flash memory device 710.

A static random access memory (SRAM) 721 may be used as an operating memory of a central processing unit (CPU) 722. A host interface (I/F) 723 may include a data exchange protocol of a host that is connected to the memory card 700. An error correction code (ECC) block 724 may detect and correct an error of data read from the multi-bit flash memory device 710. A memory interface (I/F) 725 may interface with the flash memory device 710. The processing unit 722 may perform various control operations for data exchange of the memory controller 720. Although not illustrated in the drawings, the memory card 700 may further include ROM for storing code data to interface with a host.

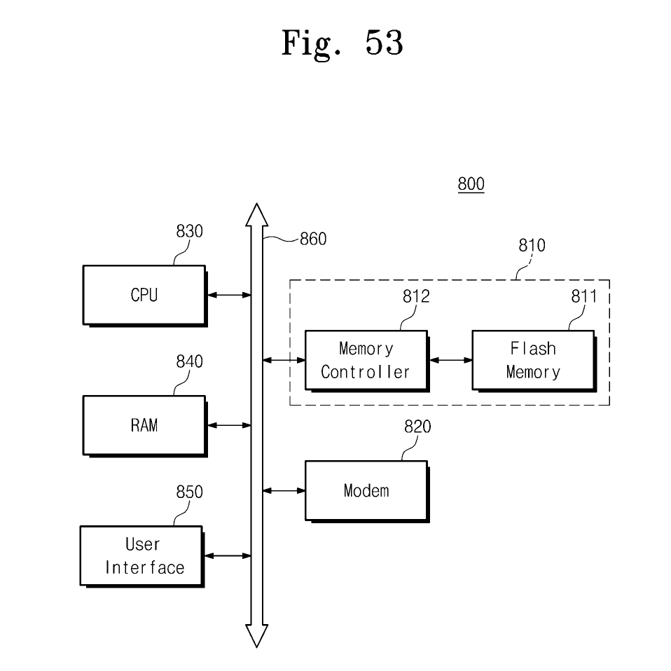

FIG. 53 illustrates a block diagram showing an information processing system provided with a semiconductor memory device formed according to an embodiment.

Referring to FIG. 53, a flash memory system 810 of an embodiment may be installed on an information processing system, e.g., a mobile device or a desktop computer. The information processing system 800 may include a flash memory system 810, a modem 820, a central processing unit (CPU) 830, a RAM 840, and a user interface 850, which may be electrically connected to a system bus 860. The flash memory system 810 may include a flash memory 811 and a memory controller 812 controlling the flash memory 811. The flash memory system 810 may have substantially the same configuration as the above described memory system or flash memory system. The flash memory system 810 may store data processed by the CPU 830 or data inputted from the outside. Here, the flash memory system 810 may include solid state disk (SSD), and in that case, the information processing system 800 may stably store a high capacity data in the flash memory system 810. Moreover, as reliability may be enhanced, the flash memory system 810 may save a resource consumed for an error correction, such that a high speed data exchange function may be provided to the information processing system 800. Although not illustrated in the drawings, the information processing system 800 may further include, e.g., an application chipset, a camera image processor (CIS), and an input/output device.

Moreover, a flash memory device or a memory system according to the embodiments may be mounted as various types of packages. For example, a flash memory device or a memory system according to an embodiment may be packaged and mounted using a method such as package on package (PoP), ball grid arrays (BGA), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline integrated circuit (SOIC), shrink small outline package (SSOP), thin small outline package (TSOP), thin Quad flatpack (TQFP), system in package (SIP), multi chip package (MCP), wafer-level fabricated package (WFP), and wafer-level processed stack package (WSP).

According to the embodiments, the semiconductor patterns used as channels of three-dimensionally arrayed transistors may include the first and second silicon films. Excellent cell current may be ensured by the grain size of the first silicon film; and excellent step coverage properties may be ensured by the second silicon film. Accordingly, the semiconductor patterns may have an excellent step coverage properties. Thus, transistors constituting a string may have the uniformity of a cell current.

Accordingly, the embodiments provide a process technology for forming a three-dimension memory device having a manufacturing cost per bit that is lower than that of a two-dimension semiconductor memory device while still ensuring reliability of a product.

The embodiments provide a method of forming a semiconductor memory device having excellent electrical characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A method of forming a semiconductor memory device, the method comprising:
forming a thin film structure on a semiconductor substrate such that the thin film structure includes a plurality of thin films;
patterning the thin film structure to form a through region in the thin film structure;
forming a first silicon film using a first precursor such that the first silicon film covers the through region; and
forming a second silicon film on the first silicon film using a second precursor,
wherein the first precursor is different from the second precursor.

2. The method as claimed in claim 1, wherein a grain size of the first silicon film is greater than a grain size of the second silicon film.

3. The method as claimed in claim 1, wherein:
the first precursor is a disilane first precursor, and
the second precursor is a silane second precursor.

4. The method as claimed in claim 3, wherein forming the first silicon film includes:
forming a first preliminary silicon film using the disilane first precursor; and
performing a heat treatment process on the first preliminary silicon film to re-crystallize the first preliminary silicon film.

5. The method as claimed in claim 4, wherein the heat treatment process is performed after the second silicon film is formed.

6. The method as claimed in claim 3, further comprising forming a third silicon film on the second silicon film, wherein the third silicon film is formed using a disilane precursor and a silane precursor.

7. The method as claimed in claim 1, wherein:
the first precursor is a trisilane first precursor, and
the second precursor is a silane second precursor.

8. The method as claimed in claim 7, further comprising forming a third silicon film on the second silicon film, wherein the third silicon film is formed using a trisilane precursor and a silane precursor.

9. The method as claimed in claim 1, further comprising forming a third silicon film covering the through region prior to forming of the first silicon film,
wherein:
the third silicon film is formed using a trisilane precursor,
the first precursor is a disilane first precursor, and
the second precursor is a silane second precursor.

10. The method as claimed in claim 1, wherein:
the thin film structure includes first insulation films and second insulation films, and
the first insulation films and second insulation films are alternately stacked.

11. The method as claimed in claim 10, further comprising:
forming a dividing region extending through the first insulation film and the second insulation film;
selectively removing portions of the second insulation film exposed through the dividing region to form an undercut region such that the undercut region exposes portions of the first silicon film between the first insulation films; and
forming a gate pattern such that the gate pattern fills the undercut region.

12. The method as claimed in claim 11, further comprising forming an information storage film between the gate pattern and the first silicon film.

13. The method as claimed in claim 12, wherein forming the information storage film includes forming a charge trap layer having a charge trap site.

14. The method as claimed in claim 1, wherein forming the thin film structure includes forming insulation films and conductive films such that the insulation films and the conductive films are alternately stacked.

15. The method as claimed in claim 14, wherein:
patterning the thin film structure includes patterning the conductive film to form conductive patterns, and
a semiconductor film including the first silicon film and the second silicon film is a channel region of three-dimensionally arrayed transistors.

16. The method as claimed in claim 15, further comprising forming an information storage film between the conductive patterns and the semiconductor film.

17. The method as claimed in claim 16, wherein forming the information storage film includes forming a charge trap layer having a charge trap site.

18-20. (canceled)
